(19) United States
(12) Patent Application Publication
(10) Pub. No.: US 2026/0074163 A1
(43) Pub. Date: Mar. 12, 2026

(54) PLASMA PROCESSING APPARATUS AND SUBSTRATE SUPPORT

(71) Applicant: Tokyo Electron Limited, Tokyo (JP)

(72) Inventors: Hiroki SATO, Miyagi (JP); Takumi IMAHASHI, Miyagi (JP); Sho OIKAWA, Miyagi (JP); Yuki KUMAGAI, Miyagi (JP); Keigo NAKAMURA, Miyagi (JP); Manabu ISHIKAWA, Miyagi (JP); Takashi NOMURA, Miyagi (JP)

(73) Assignee: Tokyo Electron Limited, Tokyo (JP)

(21) Appl. No.: 19/392,207

(22) Filed: Nov. 18, 2025

Related U.S. Application Data
(63) Continuation of application No. PCT/JP2025/008770, filed on Mar. 10, 2025.

(30) Foreign Application Priority Data
May 13, 2024 (JP) 2024-077965

(51) Int. Cl. H01J 37/32

(52) U.S. Cl. CPC H01J 37/32697; H01J 37/32091; H01J 37/32183; H01J 37/32642; H01J 37/32715; H01J 2237/334

(57) ABSTRACT

A plasma processing apparatus includes a chamber, a bias power supply to supply a pulsed bias DC signal, a substrate support to support a substrate and an edge ring in the chamber, and an electrical path. The substrate support has an electrostatic chuck that includes a first region to hold the substrate and a second region provided around the first region and to hold the edge ring, and is formed from a dielectric, a first bias electrode inside the first region, a second bias electrode inside the second region, a base to support the electrostatic chuck, and a first impedance adjustment mechanism to have a first variable capacitor connected between the second bias electrode and the base.

### CROSS-REFERENCE TO RELATED APPLICATIONS

This application is a bypass continuation application of international application No. PCT/JP2025/008770 having an international filing date of Mar. 10, 2025 and designating the United States, the international application being based upon and claiming the benefit of priority from Japanese Patent Application No. 2024-077965, filed on May 13, 2024, the entire contents of each are incorporated herein by reference.

### BACKGROUND

### Field

An exemplary embodiment of the present disclosure relates to a plasma processing apparatus and a substrate support.

### Description of Related Art

Japanese Patent Application Laid-Open No. 2023-87396 discloses a plasma processing apparatus including a chamber, a bias power supply configured to generate an electrical bias, a substrate support configured to support a substrate and an edge ring in the chamber, the substrate support including a first region configured to hold the substrate, a second region provided to surround the first region and configured to hold the edge ring, a first bias electrode provided in the first region to receive the electrical bias, a first impedance adjustment electrode provided in the first region and grounded, a second bias electrode provided in the second region to receive the electrical bias, a second impedance adjustment electrode provided in the second region and grounded, an impedance adjustment mechanism connected to at least one of the first impedance adjustment electrode and the second impedance adjustment electrode, and an electrical path connecting the bias power supply, the first bias electrode, and the second bias electrode.

### SUMMARY

A plasma processing apparatus in one exemplary embodiment of the present disclosure includes a chamber; a bias power supply configured to supply a pulsed bias DC signal; a substrate support configured to support a substrate and an edge ring in the chamber; and an electrical path. The substrate support is configured to have an electrostatic chuck that includes a first region configured to hold the substrate and a second region provided around the first region and configured to hold the edge ring, and is formed from a dielectric, a first bias electrode provided inside the first region, a second bias electrode provided inside the second region, a base configured to support the electrostatic chuck, and a first impedance adjustment mechanism configured to have a first variable capacitor connected between the second bias electrode and the base. The electrical path has a first electrical path configured to connect the bias power supply, the base, and the first bias electrode, and a second electrical path configured to connect the bias power supply, the base, the first impedance adjustment mechanism, and the second bias electrode.

### BRIEF DESCRIPTION OF DRAWINGS

The scope of the present disclosure is best understood from the following detailed description of exemplary embodiments when read in conjunction with the accompanying drawings.

FIG. 1 is a diagram illustrating an example of a configuration of a plasma processing apparatus according to an embodiment of the present disclosure.

FIG. 2 is a diagram illustrating an example of an electrical connection between a substrate support and a plasma in the present embodiment.

FIG. 3 is a diagram illustrating an example of an equivalent circuit of the substrate support and the plasma in the present embodiment.

FIG. 4 is a diagram illustrating an example of electrical connection between a substrate support and a plasma in a reference example.

FIG. 5 is a diagram illustrating an example of an equivalent circuit of the substrate support and the plasma in the reference example.

FIG. 6 is a graph illustrating an example of a relationship between an impedance of a plasma processing chamber and a capacitance of a variable capacitor in the present embodiment.

FIG. 7 is a graph illustrating an example of a relationship between the impedance on a ring assembly side and the capacitance of the variable capacitor in the present embodiment.

FIG. 8 is a graph illustrating an example of a relationship between an impedance of a plasma processing chamber and a capacitance of a variable capacitor in the reference example.

FIG. 9 is a graph illustrating an example of a relationship between the impedance on a ring assembly side and the capacitance of the variable capacitor in the reference example.

FIG. 10 is a graph illustrating an example of a relationship between a potential and the capacitance of the variable capacitor in the present embodiment.

FIG. 11 is a graph illustrating an example of a change in an etching rate in the present embodiment.

FIG. 12 is a graph illustrating an example of a relationship between a potential and the capacitance of the variable capacitor in the reference example.

FIG. 13 is a graph illustrating an example of a change in an etching rate in the reference example.

FIG. 14 is a diagram illustrating an example of tilt control of an end portion of the substrate in the present embodiment.

FIG. 15 is a diagram illustrating an example of tilt control of the end portion of the substrate in the present embodiment.

FIG. 16 is a diagram illustrating an example of an impedance adjustment mechanism in Modification Example 1.

FIG. 17 is a diagram illustrating an example of an impedance adjustment mechanism in Modification Example 2.

FIG. 18 is a diagram illustrating an example of an electrostatic chuck and a base in Modification Example 3.

FIG. 19 is a diagram illustrating an example of an electrostatic chuck and a base in Modification Example 4.

FIG. 20 is a diagram for describing a configuration example of a plasma processing apparatus when an annular conductor is disposed.

FIG. 21 is a diagram for describing a configuration example of a second conductor having the annular conductor.

FIG. 22 is a plan view of the annular conductor for describing connection positions of a plurality of second connection conductors.

FIG. 23 is a diagram for describing a configuration example of the plasma processing apparatus when a connector is disposed.

FIG. 24 is a diagram for describing a configuration example of the plasma processing apparatus when the connector has a fitting structure.

FIG. 25 is a diagram for describing a configuration example of the plasma processing apparatus when the connector has a touch structure.

FIG. 26 is a plan view of the annular conductor for describing an example of a plurality of conductor regions included in the annular conductor.

FIG. 27 is a side view of the annular conductor for describing an example of the plurality of conductor regions included in the annular conductor.

FIG. 28 is a side view illustrating an example of the annular conductor having a plurality of conductor regions having different cross-sectional areas.

FIG. 29 is a side view illustrating an example of the annular conductor having the plurality of conductor regions having different cross-sectional areas.

FIG. 30 is a diagram for describing a configuration example of the plasma processing apparatus when the variable capacitor is disposed in each of a plurality of second connection conductors.

FIG. 31 is a diagram for describing a configuration example of the plasma processing apparatus when the variable capacitor is disposed in each of a plurality of connection conductors.

FIG. 32 is a diagram for describing a configuration example of the plasma processing apparatus when a sensor is disposed.

FIG. 33 is a diagram for describing another configuration example of the plasma processing apparatus when the sensor is disposed.

FIG. 34 is a diagram for describing another configuration example of the substrate support of the plasma processing apparatus.

FIG. 35 is a diagram for describing a configuration example of the substrate support when the impedance adjustment mechanism has an additional capacitor.

FIG. 36 is a plan view of the substrate support for describing an example of disposition of a first variable capacitor and an additional capacitor.

FIG. 37 is a diagram for describing an electrical circuit formed in a plasma sheath of the edge ring and the substrate support.

FIG. 38 is a diagram for describing a configuration example of the substrate support when an additional coil is connected to a conductor to which the additional capacitor is connected.

FIG. 39 is a diagram for describing a configuration example of the substrate support when an additional coil is connected to the conductor to which the first variable capacitor is connected.

FIG. 40 is a diagram for describing a configuration example of the substrate support when an LC series circuit is connected to a node of the conductor to which the first variable capacitor is connected.

FIG. 41 is a diagram for describing a configuration example of the substrate support having a ground case surrounding the conductor to which the first variable capacitor is connected.

FIG. 42 is a diagram for describing a configuration example of the substrate support including a plurality of connection conductors electrically connecting the first variable capacitor and the second bias electrode in parallel, and having aligned path lengths of the plurality of connection conductors.

FIG. 43 is a plan view of the second bias electrode for describing an example of disposition of connection points between the plurality of connection conductors and the second bias electrode.

FIG. 44 is a diagram for describing a configuration example of the substrate support in which an impedance element is connected to at least one of the plurality of connection conductors.

FIG. 45 is a diagram for describing another configuration example of the plasma processing apparatus having a first impedance adjustment mechanism.

FIG. 46 is a diagram for describing another configuration example of the plasma processing apparatus having the first impedance adjustment mechanism.

FIG. 47 is a diagram for describing a configuration example of the plasma processing apparatus when the bias power supply has an RF power supply and a DC power supply.

### DETAILED DESCRIPTION

Hereinafter, embodiments of a plasma processing apparatus and a substrate support to be disclosed will be described in detail with reference to the drawings. The disclosed technology is not limited to the following embodiments.

In the plasma processing apparatus, a potential of an edge ring may be controlled for tilt control of an end portion of a substrate of a processing target. For example, it is proposed to provide an electrode at a position corresponding to the edge ring in an electrostatic chuck in the substrate support and control a capacitance of a variable capacitor provided between the electrode and a ground. In addition, in the plasma processing apparatus, in order to monochromatize ion energy or to make an ion angle perpendicular, for example, it is proposed to use a DC (direct current) pulse power supply that supplies a pulsed DC signal as a power supply connected to the substrate support. However, when the DC pulse power supply is used, when the capacitance of the variable capacitor provided between the electrode in the electrostatic chuck and the ground (grounding) is changed, an impedance of a chamber as viewed from a DC pulse power supply side fluctuates. Since the impedance of the chamber fluctuates, an output current of the DC pulse power supply also fluctuates. Therefore, a potential of the base of the substrate support to which the DC pulse power supply is connected may also fluctuate, and a process shift may occur. That is, the potential of the substrate, which is substantially equal to the potential of the base, fluctuates. Therefore, it is expected that fluctuation in the potential of the base is able to be suppressed even when the pulsed DC signal is supplied.

### Configuration of Plasma Processing Apparatus 1

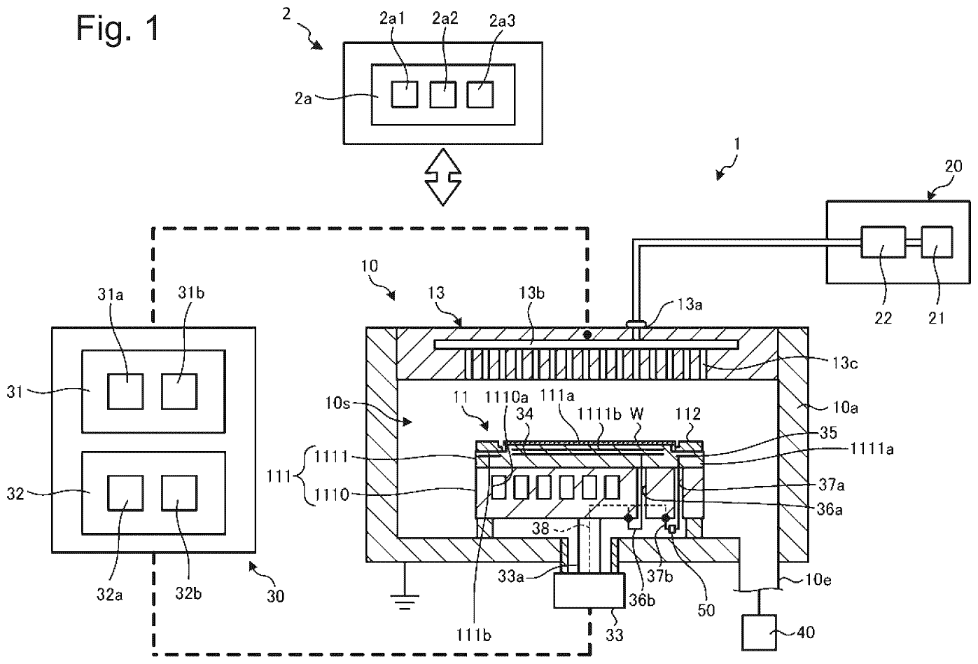

Hereinafter, a configuration example of a plasma processing system will be described. FIG. 1 is a diagram illustrating an example of a configuration of a plasma processing apparatus according to an embodiment of the present disclosure. The plasma processing system includes a capacitively coupled plasma processing apparatus 1 and a controller 2 (herein controller means the same as controller circuitry). The capacitively coupled plasma processing apparatus 1 includes a plasma processing chamber 10, a gas supply 20, a power supply 30, and an exhaust system 40. In addition, the plasma processing apparatus 1 includes a substrate support 11 and a gas introducer. The gas introducer is configured to introduce at least one processing gas into the plasma processing chamber 10. The gas introducer includes a shower head 13. The substrate support 11 is disposed in the plasma processing chamber 10. The shower head 13 is disposed above the substrate support 11. In an embodiment, the shower head 13 configures at least a part of a ceiling of the plasma processing chamber 10. The plasma processing chamber 10 has a plasma processing space 10s defined by the shower head 13, a side wall 10a of the plasma processing chamber 10, and the substrate support 11. The plasma processing chamber 10 has at least one gas supply port for supplying at least one processing gas to the plasma processing space 10s and at least one gas exhaust port for exhausting the gas from the plasma processing space 10s. The plasma processing chamber 10 is grounded. The shower head 13 and the substrate support 11 are electrically insulated from a housing of the plasma processing chamber 10.

The substrate support 11 includes a main body 111 and a ring assembly 112. The main body 111 has a center region 111a for supporting a substrate W and an annular region 111b for supporting the ring assembly 112. A wafer is an example of the substrate W. The annular region 111b of the main body 111 surrounds the center region 111a of the main body 111 in plan view. The substrate W is disposed on the center region 111a of the main body 111, and the ring assembly 112 is disposed on the annular region 111b of the main body 111 to surround the substrate W on the center region 111a of the main body 111. Therefore, the center region 111a is also referred to as a substrate support surface for supporting the substrate W, and the annular region 111b is also referred to as a ring support surface for supporting the ring assembly 112. The substrate support 11 is an example of the substrate support, the center region 111a is an example of a first region, and the annular region 111b is an example of a second region. In addition, in the following description, the center region 111a may be represented as a substrate support surface 111a, and the annular region 111b may be represented as a ring support surface 111b.

In an embodiment, the main body 111 includes a base 1110 and an electrostatic chuck 1111. The base 1110 includes a conductive member. The conductive member of the base 1110 may function as a lower electrode. That is, the conductive member of the base 1110 may function as a part of an electrical path 38 connected to a first bias electrode 34 and a second bias electrode 35, which will be described later. A power supply line 33a is connected to a bottom portion of the base 1110. The electrical path 38 also includes the power supply line 33a. The electrostatic chuck 1111 is disposed on the base 1110. The electrostatic chuck 1111 includes a ceramic member 1111a and an electrostatic electrode 1111b disposed in the ceramic member 1111a. The ceramic member 1111a has the center region 111a. In an embodiment, the ceramic member 1111a also has the annular region 111b. Another member that surrounds the electrostatic chuck 1111 may have the annular region 111b, such as an annular electrostatic chuck or an annular insulating member. In this case, the ring assembly 112 may be disposed on the annular electrostatic chuck or the annular insulating member, or may be disposed on both the electrostatic chuck 1111 and the annular insulating member. In addition, at least one RF/DC electrode coupled to a radio frequency (RF) power supply 31 and/or a direct current (DC) power supply 32, which will be described later, may be disposed in the ceramic member 1111a. In this case, at least one RF/DC electrode functions as the lower electrode. That is, the first bias electrode 34 and the second bias electrode 35, which are examples of the RF/DC electrode, which will be described later, are electrically connected to the RF power supply 31 and/or the DC power supply 32 via the electrical path 38. When a bias RF signal and/or a DC signal, which will be described later, are supplied to at least one RF/DC electrode, the RF/DC electrode is also referred to as a bias electrode. The conductive member of the base 1110 and at least one RF/DC electrode may function as a plurality of lower electrodes. In addition, the electrostatic electrode 1111b may function as the lower electrode, or the first bias electrode 34 may function as the electrostatic electrode. Therefore, the substrate support 11 includes at least one lower electrode.

The ring assembly 112 includes one or a plurality of annular members. In an embodiment, one or the plurality of annular members includes one or a plurality of edge rings and at least one cover ring. The edge ring is formed from a conductive material or an insulating material, and the cover ring is formed from an insulating material.

In addition, the substrate support 11 may include a temperature-controlled module configured to adjust at least one of the electrostatic chuck 1111, the ring assembly 112, and the substrate W to a target temperature. The temperature-controlled module may include a heater, a heat transfer medium, a flow passage 1110a, or a combination thereof. A heat transfer fluid such as brine or a gas flows in the flow passage 1110a. In an embodiment, the flow passage 1110a is formed in the base 1110, and one or a plurality of the heaters is disposed in the ceramic member 1111a of the electrostatic chuck 1111. Further, the substrate support 11 may include a heat transfer gas supply configured to supply the heat transfer gas to a gap between a back surface of the substrate W and the center region 111a.

The electrostatic chuck 1111 includes the electrostatic electrode 1111b and the first bias electrode 34 inside in order from a substrate support surface 111a side in a lower portion of the substrate support surface 111a, and is formed from the ceramic member 1111a which is a dielectric. In addition, the electrostatic chuck 1111 includes the second bias electrode 35 inside in the lower portion of the ring support surface 111b. The first bias electrode 34 is connected to, for example, a bottom portion of the base 1110 via a conductor 36b passing through a through-hole 36a of the base 1110. An insulating sleeve is provided inside the through-hole 36a, and the base 1110 and the conductor 36b are electrically insulated from each other inside the through-hole 36a. The second bias electrode 35 is connected to, for example, the bottom portion of the base 1110 via the conductor 37b passing through the through-hole 37a of the base 1110 and an impedance adjustment mechanism 50. An insulating sleeve is provided inside the through-hole 37a, and the base 1110 and the conductor 37b are electrically insulated from each other inside the through-hole 37a.

That is, the first bias electrode 34 is connected to a matching circuit 33, which will be described later, via the conductor 36b, the base 1110, and the power supply line 33a, and the electrical path 38 (first electrical path) is formed. In addition, the second bias electrode 35 is connected to a matching circuit 33, which will be described later, via the conductor 37b, the impedance adjustment mechanism 50, the base 1110, and the power supply line 33a, and an electrical path 38 (second electrical path) is formed. The connection between the first bias electrode 34, the second bias electrode 35, and the base 1110 is not limited to the conductive member, and for example, any method capable of supplying a bias RF/DC signal such as magnetic resonance, capacitive coupling, and inductive coupling may be used. That is, the electrical path 38 is configured to connect the bias power supply (for example, a second RF generator 31b and/or a first DC generator 32a, which will be described later), the first bias electrode 34, and the second bias electrode 35. In addition, the electrical path 38 may not be connected to the base 1110 by the second RF generator 31b and/or the first DC generator 32a, which will be described later, and the second RF generator 31b and/or the first DC generator 32a, and the first bias electrode 34 may be directly connected to each other. Similarly, the electrical path 38 may be directly connected to the second RF generator 31b and/or the first DC generator 32a, and the second bias electrode 35 via the impedance adjustment mechanism 50.

The impedance adjustment mechanism 50 adjusts an amount of the RF/DC signal (electrical bias) supplied from the second bias electrode 35 to a plasma side. That is, the impedance adjustment mechanism 50 adjusts the power supplied to the plasma via the ring assembly 112, in the substrate W and the ring assembly 112. That is, the impedance adjustment mechanism 50 adjusts the potential of the ring assembly 112 by adjusting the amount of the RF/DC signal flowing to the ring assembly 112 side, and the potential is used for controlling the tilt angle and/or adjusting the etching rate. Since elements configuring the electrical path 38 including the impedance adjustment mechanism 50 distribute the bias RF/DC signal to the substrate W and the ring assembly 112, the elements may also be represented as a bias split mechanism in the following description.

The first bias electrode 34 and the second bias electrode 35 are brought as close to the substrate W and the ring assembly 112 as possible, and thus the impedance of the capacitor configured to include the substrate W, the ring assembly 112, the ceramic member 1111a, and the electrodes is decreased. Accordingly, it can decrease each potential difference between the first bias electrode 34 and the second bias electrode 35, and the substrate W and the ring assembly 112. Similarly, the impedance of the capacitor configured to include each of the first bias electrode 34 and the electrostatic electrode 1111b may also be decreased. In addition, the impedance of the capacitor configured to include each of the electrostatic electrode 1111b and the substrate W, and the second bias electrode 35 and the ring assembly 112 is able to also be decreased.

The impedance adjustment mechanism may be provided in the conductor 36b for the electrical path 38 (first electrical path) on the substrate support surface 111a side. In this case, the first bias electrode 34 is connected to the matching circuit 33, which will be described later, via the conductor 36b, the impedance adjustment mechanism, the base 1110, and the power supply line 33a, and the electrical path 38 is formed.

As described above, the substrate support 11 is configured to have the electrostatic chuck 1111, the first bias electrode 34, the second bias electrode 35, the base 1110, and the impedance adjustment mechanism (first impedance adjustment mechanism) 50 (herein first impedance adjustment circuitry means the same as first impedance adjustment mechanism). The electrostatic chuck 1111 includes the first region that holds the substrate W and the second region which is provided around the first region and holds the edge ring, and is formed from the dielectric. The first bias electrode 34 is provided inside the first region. The second bias electrode 35 is provided inside the second region. The base 1110 supports the electrostatic chuck 1111. The impedance adjustment mechanism 50 is configured to have a variable capacitor 51 (first variable capacitor), which will be described later, which is connected between the second bias electrode 35 and the base 1110. In addition, the ring assembly 112 (edge ring), the second region, and the second bias electrode 35 are formed in an annular shape. In addition, the substrate support 11 is formed and thus the first region and the second region of the electrostatic chuck 1111 are integrated.

The shower head 13 is configured to introduce at least one processing gas into the plasma processing space 10s from the gas supply 20. The shower head 13 has at least one gas supply port 13a, at least one gas diffusion chamber 13b, and a plurality of gas introduction ports 13c. The processing gas supplied to the gas supply port 13a passes through the gas diffusion chamber 13b and is introduced into the plasma processing space 10s from the plurality of gas introduction ports 13c. In addition, the shower head 13 includes at least one upper electrode. In addition to the shower head 13, the gas introducer may include one or a plurality of side gas injectors (SGI) attached to one or a plurality of opening portions formed on the side wall 10a.

The gas supply 20 may include at least one gas source 21 and at least one flow rate controller 22. In an embodiment, the gas supply 20 is configured to supply at least one processing gas to the shower head 13 from each corresponding gas source 21 via each corresponding flow rate controller 22. Each flow rate controller 22 may include, for example, a mass flow controller or a pressure-controlled flow rate controller. Furthermore, the gas supply 20 may include one or more flow rate modulation devices that modulate or pulse the flow rate of at least one processing gas.

The power supply 30 includes the RF power supply 31 coupled to the plasma processing chamber 10 via at least one impedance matching circuit. The RF power supply 31 is configured to supply at least one RF signal (RF power) to at least one lower electrode (first bias electrode 34, second bias electrode 35) and/or at least one upper electrode. As a result, the plasma is formed from at least one processing gas supplied to the plasma processing space 10s. Therefore, the RF power supply 31 may function as at least a part of a plasma generator configured to form the plasma from one or more processing gases in the plasma processing chamber 10. Further, by supplying the bias RF/DC signal to at least one lower electrode, a bias potential is generated in the substrate W, and an ion component in the formed plasma is able to be drawn into the substrate W.

In an embodiment, the RF power supply 31 includes a first RF generator 31a and a second RF generator 31b. The first RF generator 31a is coupled to at least one lower electrode and/or at least one upper electrode via at least one impedance matching circuit and is configured to generate a source RF signal (source RF power) for plasma formation. For example, when the first RF generator 31a is coupled to the lower electrode, the first RF generator 31a is coupled to the first bias electrode 34 via the matching circuit 33, the power supply line 33a, the base 1110, and the conductor 36b. In addition, the first RF generator 31a is coupled to the second bias electrode 35 via the matching circuit 33, the power supply line 33a, the base 1110, the conductor 37b, and the impedance adjustment mechanism 50. In an embodiment, the source RF signal has a frequency in the range of 10 MHz to 150 MHz. In an embodiment, the first RF generator 31a may be configured to generate a plurality of source RF signals having different frequencies. The generated one or the plurality of source RF signals is supplied to at least one lower electrode and/or at least one upper electrode. That is, the source RF signal is supplied to at least one lower electrode and/or at least one upper electrode in the plasma processing chamber 10 so as to generate the capacitively coupled plasma.

The second RF generator 31b is coupled to the first bias electrode 34 via the matching circuit 33, the power supply line 33a, the base 1110, and the conductor 36b. In addition, the second RF generator 31b is coupled to the second bias electrode 35 via the matching circuit 33, the power supply line 33a, the base 1110, the conductor 37b, and the impedance adjustment mechanism 50. The second RF generator 31b is configured to generate the bias RF signal (bias RF power). The frequency of the bias RF signal may be the same as or different from the frequency of the source RF signal. In an embodiment, the bias RF signal has a frequency lower than the frequency of the source RF signal. In an embodiment, the bias RF signal has the frequency in the range of 100 kHz to 60 MHz. In an embodiment, the second RF generator 31b may be configured to generate a plurality of bias RF signals having different frequencies. The generated one or the plurality of bias RF signals is supplied to at least one lower electrode. In addition, in various embodiments, at least one of the source RF signal and the bias RF signal may be pulsed.

In addition, the power supply 30 may include the DC power supply 32 coupled to the plasma processing chamber 10. The DC power supply 32 includes the first DC generator 32a and the second DC generator 32b. In an embodiment, the first DC generator 32a is connected to at least one lower electrode, and is configured to generate a first DC signal. The generated first DC signal (bias DC signal) is applied to at least one lower electrode. In an embodiment, the second DC generator 32b is connected to at least one upper electrode and is configured to generate a second DC signal. The generated second DC signal is applied to at least one upper electrode.

In various embodiments, at least one of the first and second DC signals may be pulsed. In this case, a sequence of voltage pulses is applied to at least one lower electrode and/or at least one upper electrode. The voltage pulse may have a pulse waveform having a rectangular shape, a trapezoidal shape, a triangular shape, or a combination thereof. In an embodiment, a waveform generator for generating the sequence of voltage pulses from the DC signal is connected between the first DC generator 32a and at least one lower electrode. Therefore, the first DC generator 32a and the waveform generator configure the voltage pulse generator. That is, the first DC generator 32a and the waveform generator are an example of the bias power supply (DC pulse power supply) configured to supply the pulsed bias DC signal. In this case, the first DC signal (bias DC signal) may be represented as including the sequence of generated voltage pulses. That is, the first DC signal is an example of the pulsed bias DC signal. In addition, in an embodiment, the first DC generator 32a may include a waveform generator. When the second DC generator 32b and the waveform generator configure the voltage pulse generator, the voltage pulse generator is connected to at least one upper electrode. The voltage pulse may have a positive polarity or a negative polarity. In addition, the sequence of voltage pulses may include one or a plurality of voltage pulses of the positive polarity and one or a plurality of voltage pulses of the negative polarity in one cycle. The first and second DC generators 32a and 32b may be provided in addition to the RF power supply 31, or the first DC generator 32a may be provided instead of the second RF generator 31b.

The matching circuit 33 is provided between the first RF generator 31a, the second RF generator 31b, the first DC generator 32a, and the substrate support 11 (base 1110), and is connected thereto. The matching circuit 33 allows the source RF signal and/or the bias RF signal to be supplied from the first RF generator 31a and/or the second RF generator 31b to the substrate support 11 via the matching circuit 33. In addition, the matching circuit 33 allows the first DC signal (bias DC signal) to be supplied from the first DC generator 32a to the substrate support 11 via the matching circuit 33.

The exhaust system 40 may be connected to, for example, a gas exhaust port 10e provided at a bottom portion of the plasma processing chamber 10. The exhaust system 40 may include a pressure regulating valve and a vacuum pump. The pressure in the plasma processing space 10s is adjusted by the pressure regulating valve. The vacuum pump may include a turbo molecular pump, a dry pump, or a combination thereof.

The controller 2 processes a computer-executable instruction that causes the plasma processing apparatus 1 to execute various steps described in the present disclosure. The controller 2 may be configured to control each element of the plasma processing apparatus 1 to execute the various steps described here. In an embodiment, a part or all of the controller 2 may be included in the plasma processing apparatus 1. The controller 2 may include a processor 2a1, a storage 2a2, and a communication interface 2a3. The controller 2 is realized by, for example, a computer 2a. The processor 2a1 may be configured to read out a program from the storage 2a2 and to execute the read-out program to perform various control operations. This program may be stored in the storage 2a2 in advance, or may be acquired via a medium when necessary. The acquired program is stored in the storage 2a2, is read out from the storage 2a2, and executed by the processor 2a1. The medium may be various storage media readable by the computer 2a or may be a communication line connected to the communication interface 2a3. The processor 2a1 may be a central processing unit (CPU). The storage 2a2 may include a random access memory (RAM), a read only memory (ROM), a hard disk drive (HDD), a solid state drive (SSD), or a combination thereof. The communication interface 2a3 may communicate with the plasma processing apparatus 1 via a communication line such as a local area network (LAN). The controller/controller circuitry 2 can be programmable circuitry (e.g., embedded processor) or fixed circuitry (e.g., ASIC or PAL). In an exemplary embodiment, the controller/controller circuitry 2 can include one or more programmable processors/controllers.

### Bias Split Mechanism

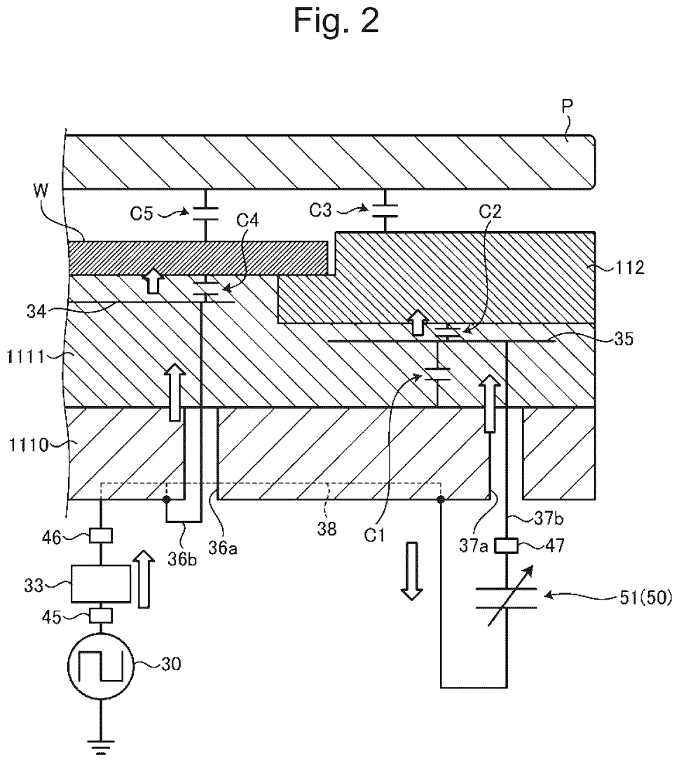

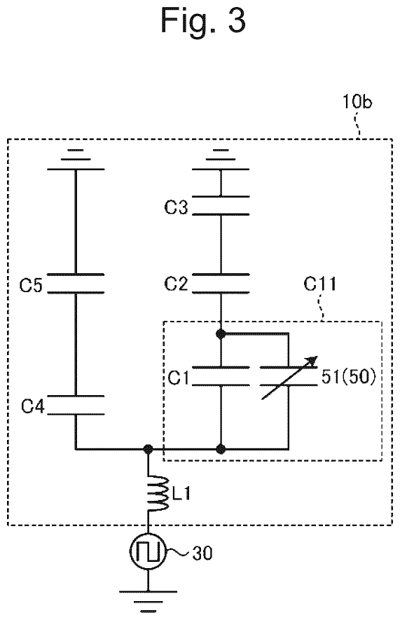

Next, a bias split mechanism for distributing the bias RF/DC signal will be described with reference to FIGS. 2 and 3. FIG. 2 is a diagram illustrating an example of an electrical connection between the substrate support and the plasma in the present embodiment. FIG. 3 is a diagram illustrating an example of an equivalent circuit of the substrate support and the plasma in the present embodiment.

As illustrated in FIG. 2, in the present embodiment, the power supply 30 is connected to supply the bias RF/DC signal to the base 1110 via the matching circuit 33. The power supply 30 includes the first RF generator 31a, the second RF generator 31b, and the first DC generator 32a that supply the bias RF/DC signal. The first bias electrode 34 is connected to the base 1110 via the conductor 36b as a part of the electrical path 38. In addition, the first bias electrode 34 is electrically connected to the substrate W via a capacitor C4 formed between the first bias electrode 34 and the substrate W by the ceramic member 1111a of the electrostatic chuck 1111. Further, the substrate W is electrically connected to a plasma P via a capacitor C5 formed between the substrate W and the plasma P generated in the plasma processing chamber 10, and is electrically grounded via the plasma processing chamber 10.

In addition, the second bias electrode 35 is connected to the base 1110 as a part of the electrical path 38 via the conductor 37b and the variable capacitor 51. Here, the variable capacitor 51 is an example of the impedance adjustment mechanism 50. In addition, the variable range of the capacitance of the variable capacitor 51 may be, for example, 10 pF to 2000 pF. The variable range of the capacitance of the variable capacitor 51 may be further widened to include at least one of a range of less than 10 pF and a range of more than 2000 pF. The impedance adjustment mechanism 50 may include other elements such as coils, capacitors, and resistors. In addition, the second bias electrode 35 is electrically connected to the base 1110 via a capacitor C1 formed between the second bias electrode 35 and the base 1110 by the ceramic member 1111a of the electrostatic chuck 1111. That is, the variable capacitor 51 and the capacitor C1 are connected in parallel between the second bias electrode 35 and the base 1110. In addition, the second bias electrode 35 is electrically connected to the ring assembly 112 via a capacitor C2 formed between the second bias electrode 35 and the ring assembly 112 (edge ring) by the ceramic member 1111a of the electrostatic chuck 1111. Further, the ring assembly 112 is electrically connected to the plasma P via a capacitor C3 formed between the ring assembly 112 and the plasma P, and is electrically grounded via the plasma processing chamber 10.

When the electrical connection between the substrate support 11 and the plasma P illustrated in FIG. 2 is represented by an equivalent circuit, an equivalent circuit 10b in FIG. 3 is obtained. As illustrated in FIG. 3, in the equivalent circuit 10b, a coil L1 is connected in series in order from the power supply 30 side, and the circuit on the ring assembly 112 side and the circuit on the substrate W side are connected in parallel. That is, the bias RF/DC signal is distributed to the ring assembly 112 side and the substrate W side. In FIG. 3, the matching circuit 33 is omitted, and the coil L1 represents a parasitic inductance. In the circuit on the ring assembly 112 side, the variable capacitor 51 and the capacitor C1 are connected in parallel, and the capacitor C2 and the capacitor C3 are connected in series, and electrically grounded. A combined capacitance of the variable capacitor 51 and the capacitor C1 is represented as a capacitance C11. On the other hand, in the circuit on the substrate W side (substrate support surface 111a side), the capacitor C4 and the capacitor C5 are connected in series and are electrically grounded. In the equivalent circuit 10b, the plasma P is omitted.

As described above, the electrical path 38 has a first electrical path and a second electrical path. The first electrical path connects the power supply 30 (bias power supply), the base 1110, and the first bias electrode 34. The second electrical path connects the power supply 30 (bias power supply), the base 1110, the impedance adjustment mechanism 50 (first impedance adjustment mechanism), and the second bias electrode 35. In addition, the plasma processing apparatus 1 may further include a second impedance adjustment mechanism having a second variable capacitor connected between the first bias electrode 34 and the base 1110 for the electrical path 38 (first electrical path) on the substrate support surface 111a side (herein second impedance adjustment circuitry means the same as second impedance adjustment mechanism). In this case, the first electrical path connects the power supply 30 (bias power supply), the base 1110, the second impedance adjustment mechanism, and the first bias electrode 34.

In FIGS. 2 and 3, even when the capacitance of the variable capacitor 51 is changed, the impedance of the plasma processing chamber 10 is constant. Therefore, when the bias DC signal pulsed by the first DC generator 32a is supplied, the potential of the ring assembly 112 is able to be controlled while the potential of the base 1110 (potential of the substrate W) is kept constant by changing the capacitance of the variable capacitor 51.

Further, in the present embodiment, when the first DC signal (bias DC signal) is supplied from the first DC generator 32a to the base 1110, the voltage or the potential of each part of the electrical path 38 may be measured, and feedback control may be performed on the first DC generator 32a. The first DC generator 32a is able to set and control an output voltage by the controller 2. In this case, the plasma processing apparatus 1 includes, for example, a voltage sensor 45, a potential sensor 46, and a potential sensor 47 (refer to FIG. 2). The voltage sensor 45 measures the output voltage of the first DC generator 32a. The potential sensor 46 measures the potential of the base 1110. The potential sensor 47 measures a potential between the variable capacitor 51 and the second bias electrode 35. The voltage sensor 45, the potential sensor 46, and the potential sensor 47 output the respective measurement values to the controller 2.

When the capacitance of the variable capacitor 51 is changed, the controller 2 controls the first DC generator 32a and thus the measurement value of the voltage sensor 45 or the potential sensor 46 becomes constant. That is, the controller 2 performs feedback control for adjusting the output voltage of the first DC generator 32a and thus the measurement value of the voltage sensor 45 or the potential sensor 46 becomes constant, based on the measurement value of the voltage sensor 45 or the potential sensor 46. In addition, the controller 2 may calculate a ratio of the potentials based on the measurement values of the potential sensor 46 and the potential sensor 47, and adjust the output voltage of the first DC generator 32a and thus the calculated ratio of the potentials is a target value.

The control parameter of the first DC generator 32a includes, for example, at least one of a frequency and a duty ratio of the voltage pulse (DC pulse) included in the first DC signal (bias DC signal). For example, the frequency of the voltage pulse is able to be 400 kHz. The frequency of the voltage pulse may be any frequency in the range of 200 Hz to 3 MHz. In addition, for example, the duty ratio of the voltage pulse is able to be set to 20%. The duty ratio of the voltage pulse may be any duty ratio of 20% or more. Since the first DC generator 32a is able to change the duty ratio of the voltage pulse, the time required for charging the electrons is able to be changed in addition to the control of the potential of the substrate W and the ring assembly 112 by being combined with the change of the capacitance of the variable capacitor 51. That is, in the plasma processing apparatus 1, tuning of the process is able to be performed by changing the time required for the charge of the electrons based on the duty ratio of the voltage pulse of the first DC generator 32a and the capacitance of the variable capacitor 51.

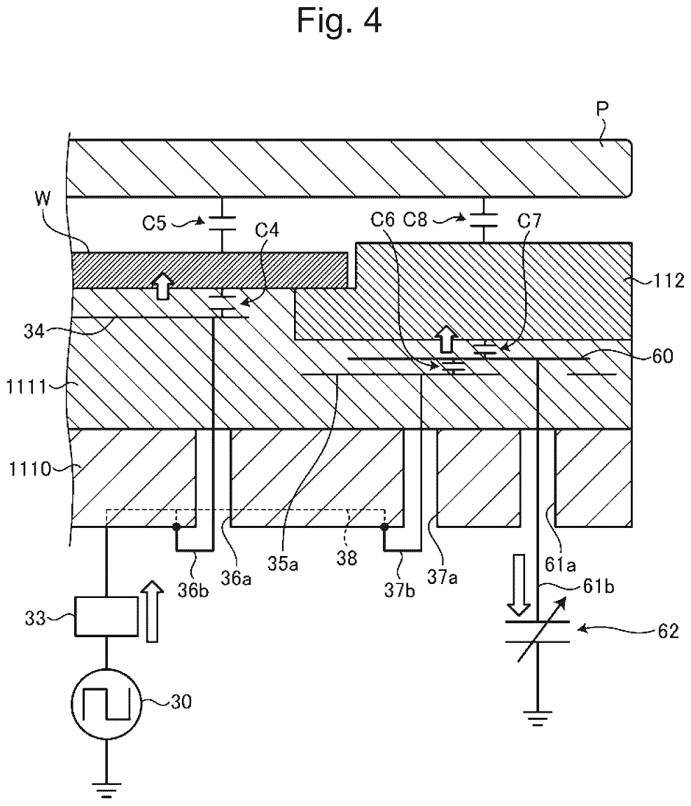

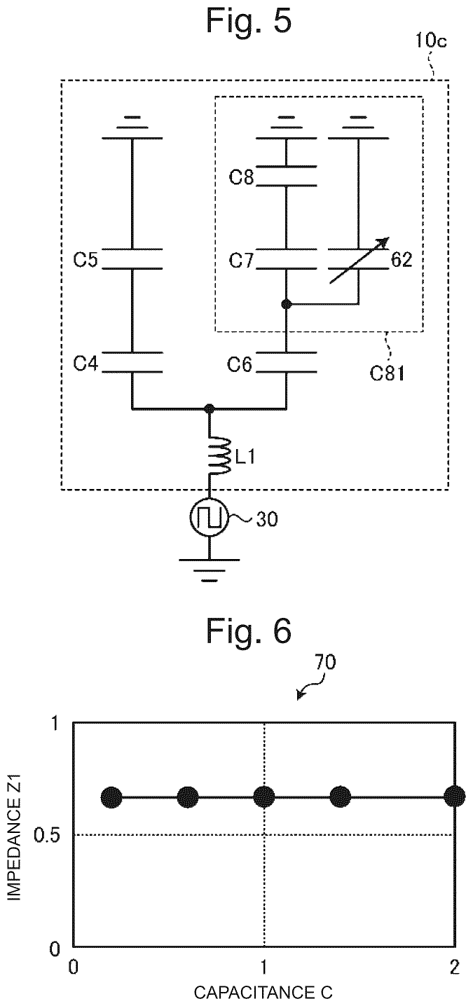

Next, a bias split mechanism of a reference example will be described with reference to FIGS. 4 and 5. FIG. 4 is a diagram illustrating an example of electrical connection between a substrate support and a plasma in the reference example. FIG. 5 is a diagram illustrating an example of an equivalent circuit of the substrate support and the plasma in the reference example.

As illustrated in FIG. 4, in the reference example, the power supply 30 is connected and thus the bias RF/DC signal is supplied from the power supply 30 to the base 1110 via the matching circuit 33. The power supply 30 includes the first RF generator 31a, the second RF generator 31b, and the first DC generator 32a that supply the bias RF/DC signal. The first bias electrode 34 is connected to the base 1110 via the conductor 36b as a part of the electrical path 38. In addition, the first bias electrode 34 is electrically connected to the substrate W via a capacitor C4 formed between the first bias electrode 34 and the substrate W by the ceramic member 1111a of the electrostatic chuck 1111. Further, the substrate W is electrically connected to the plasma P via the capacitor C5 formed between the substrate W and the plasma P, and is electrically grounded via the plasma processing chamber 10.

In addition, the second bias electrode 35a is connected to the base 1110 via the conductor 37b as a part of the electrical path 38. That is, in the reference example, the electrical path 38 does not include the variable capacitor 51. In the reference example, the impedance adjustment electrode 60 is provided on the ring assembly 112 side from the second bias electrode 35a in the electrostatic chuck 1111. The impedance adjustment electrode 60 is grounded via a conductor 61b passing through a through-hole 61a and a variable capacitor 62. Here, the variable capacitor 62 is provided to adjust the impedance on the ring assembly 112 side. As in the through-hole 36a, in the through-hole 61a, an insulating sleeve is provided inside the through-hole 61a, and the base 1110 and the conductor 61b are electrically insulated from each other inside the through-hole 61a.

The second bias electrode 35a is electrically connected to the impedance adjustment electrode 60 via a capacitor C6 formed between the second bias electrode 35a and the impedance adjustment electrode 60 by the ceramic member 1111a of the electrostatic chuck 1111. In addition, the impedance adjustment electrode 60 is electrically connected to the ring assembly 112 via a capacitor C7 formed between the impedance adjustment electrode 60 and the ring assembly 112 by the ceramic member 1111a of the electrostatic chuck 1111. Further, the ring assembly 112 is electrically connected to the plasma P via a capacitor C8 formed between the ring assembly 112 and the plasma P, and is electrically grounded via the plasma processing chamber 10. That is, the capacitors C7 and C8 connected in series, and the variable capacitor 62 are connected in parallel between the impedance adjustment electrode 60 and the ground.

When the electrical connection between the substrate support 11 and the plasma P illustrated in FIG. 4 is represented by an equivalent circuit, an equivalent circuit 10c in FIG. 5 is obtained. As illustrated in FIG. 5, in the equivalent circuit 10c, the coil L1 is connected in series in order from the power supply 30 side, and the circuit on the ring assembly 112 side and the circuit on the substrate W side are connected in parallel. That is, the bias RF/DC signal is distributed to the ring assembly 112 side and the substrate W side. In FIG. 5, the matching circuit 33 is omitted, and the coil L1 represents a parasitic inductance. In the circuit on the ring assembly 112 side, the parallel connection between the capacitors C7 and C8 which are connected in series, and the variable capacitor 62 is connected in series to the capacitor C6, and the capacitors C8 and the variable capacitor 62 are electrically grounded. The combined capacitance of the capacitors C7 and C8 connected in series, and the variable capacitor 62 connected in parallel is represented as a capacitance C81. On the other hand, in the circuit on the substrate W side (substrate support surface 111a side), the capacitor C4 and the capacitor C5 are connected in series and are electrically grounded. In the equivalent circuit 10c, the plasma P is omitted.

In FIGS. 4 and 5, when the capacitance of the variable capacitor 62 is changed, the bias DC signal flowing from the variable capacitor 62 to the ground is changed without passing through the plasma P, and thus the impedance of the plasma processing chamber 10 fluctuates. Therefore, when the pulsed bias DC signal (first DC signal) is supplied from the first DC generator 32a of the power supply 30, an output current of the first DC generator 32a changes, and the potential of the base 1110 (substantially equal to the potential of the substrate W) fluctuates. The potential of the base 1110 is represented by the following Expression (1).

Vpp=Vout+(XL×Iout) (1)

Here, Vpp indicates the potential of the base 1110 (substantially equal to the potential of the substrate W), and Vout indicates the output voltage of the first DC generator 32a before changing the capacitance of the variable capacitor 62. In addition, XL indicates the reactance on the circuit including the matching circuit 33, and Iout indicates the output current that fluctuates when the capacitance of the variable capacitor 62 is changed. In addition, (XL×Iout) in Expression (1) indicates a fluctuation amount of the output voltage of the first DC generator 32a when the capacitance of the variable capacitor 62 is changed. That is, in the reference example, the voltage applied to the base 1110 is boosted.

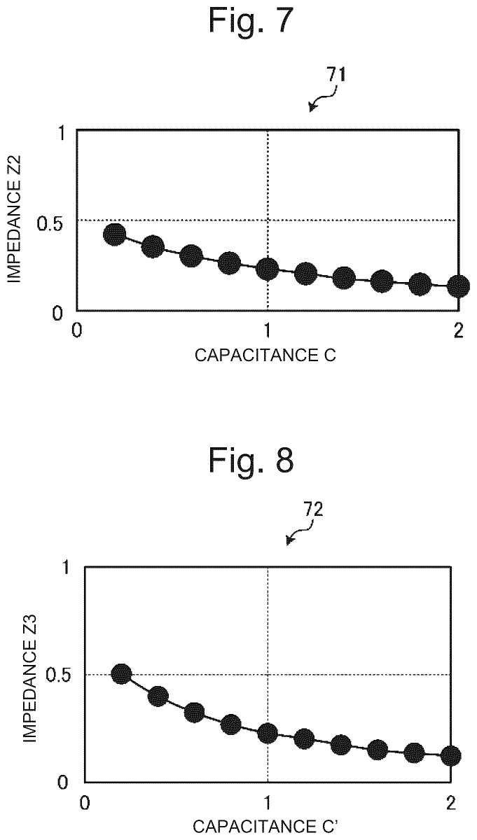

Next, the impedance of the plasma processing chamber 10 in the present embodiment and the reference example, and the impedance on the ring assembly 112 side will be compared with each other with reference to FIGS. 6 to 9. FIG. 6 is a graph illustrating an example of a relationship between the impedance of the plasma processing chamber and the capacitance of the variable capacitor in the present embodiment. FIG. 7 is a graph illustrating an example of a relationship between the impedance on the ring assembly side and the capacitance of the variable capacitor in the present embodiment. In each of the graphs of FIGS. 6 to 9, the impedance and the capacitance are normalized and represented within a predetermined range, since it is sufficient to represent the change in the impedance with respect to the change in the capacitance.

In the present embodiment, when the capacitance C of the variable capacitor 51 is changed, an impedance Z1 of the entire plasma processing chamber 10 (entire equivalent circuit 10b) is substantially constant as illustrated in a graph 70 of FIG. 6. In addition, as illustrated in a graph 71 of FIG. 7, an impedance Z2 on the ring assembly 112 side (capacitance C11 side of the equivalent circuit 10b) changes according to the capacitance C of the variable capacitor 51. That is, in the present embodiment, when the first DC signal (pulsed DC signal) is supplied, even when the capacitance C of the variable capacitor 51 is changed, the impedance Z2 on the ring assembly 112 side is able to be controlled while suppressing the fluctuation of the impedance Z1.

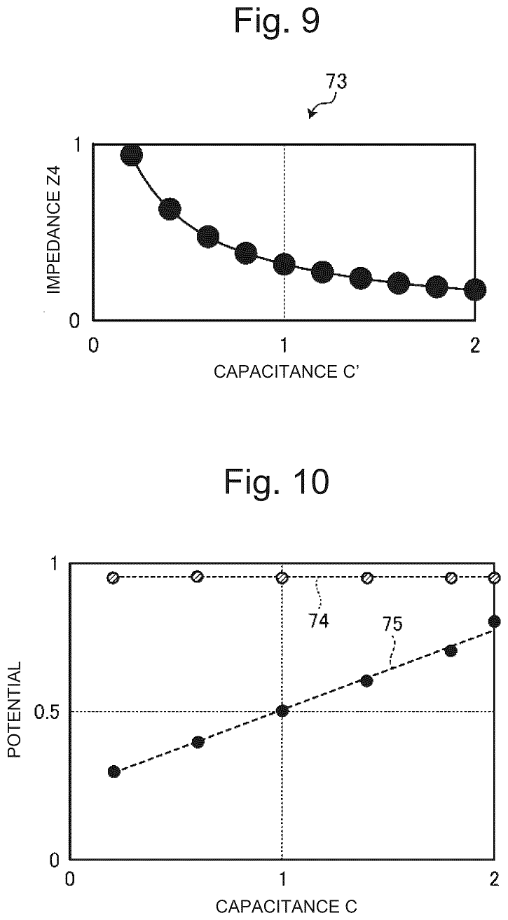

FIG. 8 is a graph illustrating an example of a relationship between the impedance of the plasma processing chamber and the capacitance of the variable capacitor in the reference example. FIG. 9 is a graph illustrating an example of a relationship between the impedance on the ring assembly side and the capacitance of the variable capacitor in the reference example. In the reference example, when a capacitance C′ of the variable capacitor 62 is changed, as illustrated in a graph 72 of FIG. 8, an impedance Z3 of the entire plasma processing chamber 10 (entire equivalent circuit 10c) changes according to the capacitance C′ of the variable capacitor 62. In addition, as illustrated in a graph 73 of FIG. 9, an impedance Z4 on the ring assembly 112 side (on a capacitance C81 side of the equivalent circuit 10c) changes according to the capacitance C′ of the variable capacitor 62. That is, in the reference example, when the first DC signal (pulsed DC signal) is supplied, when the capacitance C′ of the variable capacitor 62 is changed, not only the impedance Z4 but also the impedance Z3 is changed.

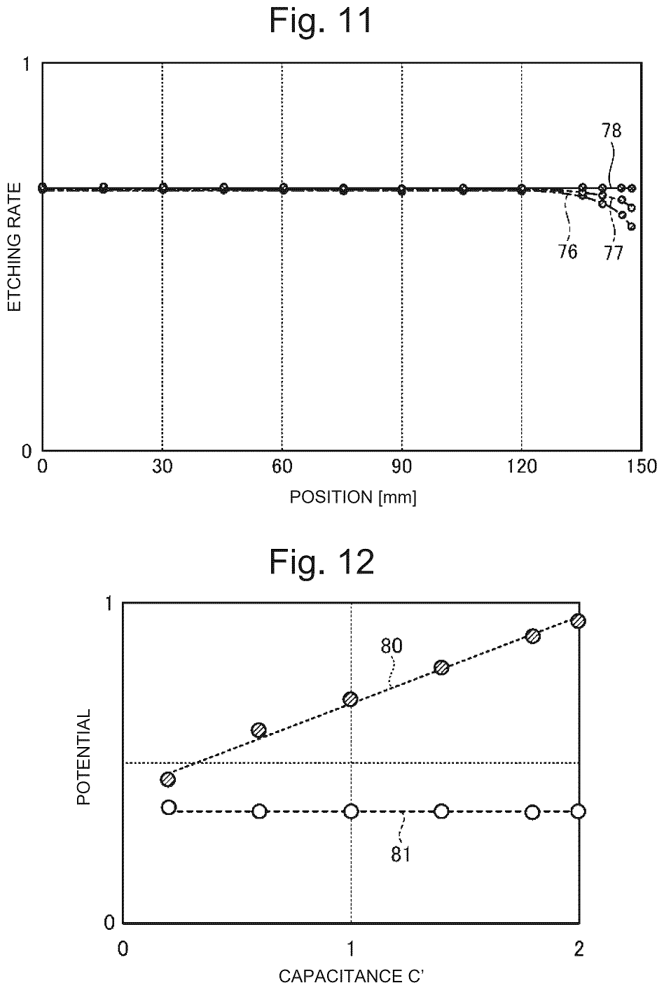

Subsequently, the potential of the base 1110 and the ring assembly 112, and the fluctuation of the etching rate in the present embodiment and the reference example will be described with reference to FIGS. 10 to 13. FIG. 10 is a graph illustrating an example of a relationship between the potential and the capacitance of the variable capacitor in the present embodiment. FIG. 11 is a graph illustrating an example of a change in the etching rate in the present embodiment. In each of the graphs of FIGS. 10 to 13, the potential, the capacitance, and the etching rate are normalized and represented within a predetermined range, since it is sufficient to represent a relative change of each of the potential, the capacitance, and the etching rate.

A graph 74 of FIG. 10 illustrates the potential of the base 1110 when the capacitance C of the variable capacitor 51 is changed. In addition, a graph 75 illustrates the potential of the ring assembly 112 when the capacitance C of the variable capacitor 51 is changed. As illustrated in the graphs 74 and 75, in the present embodiment, even when the capacitance C of the variable capacitor 51 is changed, the potential of the base 1110 (substantially equal to the potential of the substrate W) is substantially constant. In contrast, the potential of the ring assembly 112 changes and thus the potential increases as the capacitance C of the variable capacitor 51 increases. That is, the potential of the ring assembly 112 changes according to the change in the capacitance C of the variable capacitor 51. In this way, in the present embodiment, when the first DC signal (pulsed DC signal) is supplied, even when the capacitance C of the variable capacitor 51 is changed, the potential of the ring assembly 112 is able to be controlled while suppressing the fluctuation of the potential of the base 1110.

Graphs 76 to 78 of FIG. 11 illustrate an example of an etching rate of an oxide film in a radial direction of the substrate W when the capacitance C of the variable capacitor 51 is set to a minimum value, an intermediate value, and a maximum value of the graphs 74 and 75 of FIG. 10. As illustrated in the graphs 76 to 78, in the present embodiment, even when the capacitance C of the variable capacitor 51 is changed, the fluctuation of the etching rate is able to be made, for example, less than 2%.

FIG. 12 is a graph illustrating an example of a relationship between the potential and the capacitance of the variable capacitor in the reference example. A graph 80 of FIG. 12 illustrates the potential of the base 1110 when the capacitance C′ of the variable capacitor 62 is changed. In addition, a graph 81 illustrates the potential of the ring assembly 112 when the capacitance C′ of the variable capacitor 62 is changed. As illustrated in the graphs 80 and 81, in the reference example, when the capacitance C′ of the variable capacitor 62 is changed, the potential of the base 1110 (substantially equal to the potential of the substrate W) changes to increase as the capacitance C′ increases. In contrast, the potential of the ring assembly 112 is substantially constant even when the capacitance C′ of the variable capacitor 62 is changed. That is, the potential of the base 1110 changes according to the capacitance C′ of the variable capacitor 62.

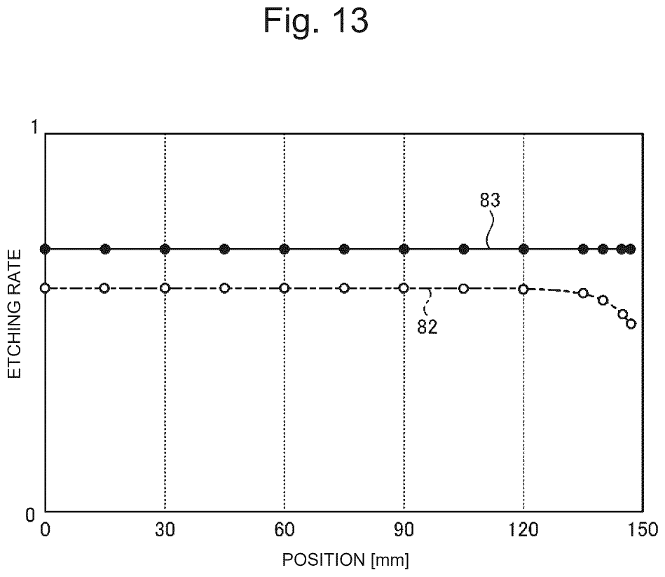

FIG. 13 is a graph illustrating an example of a change in the etching rate in the reference example. Graphs 82 and 83 of FIG. 13 illustrate an example of the etching rate of the oxide film in the radial direction of the substrate W when the capacitance C′ of the variable capacitor 62 is set to the minimum value and the maximum value of the graphs 80 and 81 of FIG. 12. As illustrated in the graphs 82 and 83, in the reference example, when the capacitance C′ of the variable capacitor 62 is changed, the fluctuation of the etching rate is, for example, about 13%. From the graphs 76 to 78 of FIG. 11 and the graphs 82 and 83 of FIG. 13, it is able to be seen that in the present embodiment, the fluctuation of the etching rate is able to be suppressed.

### Tilt Control of End Portion of Substrate

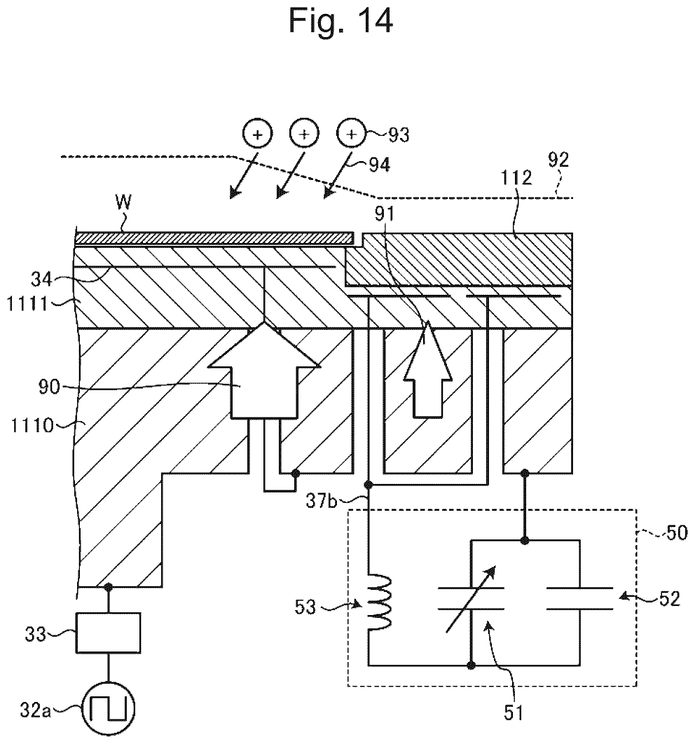

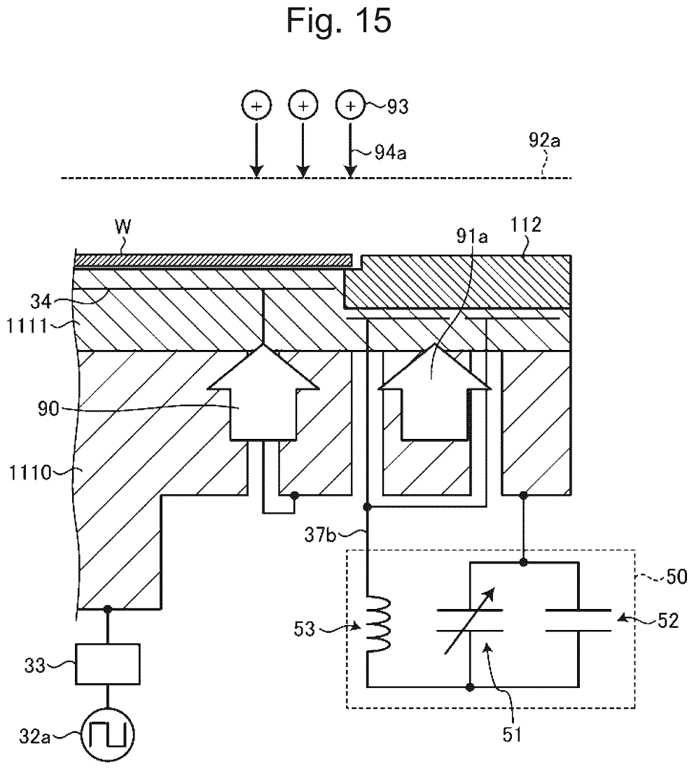

Next, the tilt control of the end portion of the substrate using the present embodiment will be described with reference to FIGS. 14 and 15. FIGS. 14 and 15 are diagrams illustrating an example of tilt control of the end portion of the substrate in the present embodiment. In the examples of FIGS. 14 and 15, the impedance adjustment mechanism 50 includes the variable capacitor 51, a capacitor 52, and a coil 53. The capacitor 52 is connected in parallel to the variable capacitor 51, and shifts a variable range of the capacitance in the impedance adjustment mechanism 50. For example, when the variable range of the capacitance of the variable capacitor 51 is 10 pF to 2000 pF, the variable range of the capacitance of the variable capacitor 51 is able to be set to 510 pF to 2500 pF by connecting the capacitor 52 having the capacitance of 500 pF in parallel. The coil 53 represents the parasitic inductance. In addition, the first DC signal is supplied to the base 1110 from the first DC generator 32a via the matching circuit 33.

The example of FIG. 14 is a case where the capacitance of the variable capacitor 51 is decreased, that is, a case where the reactance of the variable capacitor 51 is increased. In this case, when a power 90 of the first DC signal on the first bias electrode 34 side and a power 91 of the first DC signal on the second bias electrode 35 side are compared, for example, it is assumed that the power 90 flows more than the power 91. In the examples of FIGS. 14 and 15, two second bias electrodes 35 are provided on an inner peripheral side and an outer peripheral side, respectively, and the conductors 37b are connected to the second bias electrodes 35. In addition, in a plasma sheath 92, it is assumed that a height of an upper portion of the ring assembly 112 is lower than a height of an upper portion of the substrate W. The plasma sheath 92 is a line that images a predetermined potential. At this time, ions 93 generated by the plasma P are inclined and drawn toward the inside of the substrate W as indicated by a direction 94 of an electric field. That is, at an end portion of the substrate W, the direction 94 of the electric field is inclined toward the inside of the substrate W, and for example, an inner tilt is generated in which a bottom portion of a hole formed by etching is inclined toward the inside of the substrate W.

The example of FIG. 15 is a case where the capacitance of the variable capacitor 51 is increased, that is, a case where the reactance of the variable capacitor 51 is decreased. In this case, when the power 90 of the first DC signal on the first bias electrode 34 side and a power 91a of the first DC signal on the second bias electrode 35 side are compared, for example, it is assumed that the power 90 and the power 91a flow to the same extent. At this time, it is assumed that a plasma sheath 92a has substantially the same height as the upper portion of the substrate W and the upper portion of the ring assembly 112. At this time, the ions 93 generated by the plasma P are drawn in a direction perpendicular to the substrate W as indicated by a direction 94a of the electric field, and thus no tilting occurs. The example of FIG. 15 illustrates that the tilt control is able to be performed by changing the power 91a on the ring assembly 112 side. Examples of a case where the capacitance of the variable capacitor 51 is increased include a case where the ring assembly 112 is worn. In this case, the height of the ring assembly 112 itself is decreased, and the plasma sheath is also lower than the upper portion of the substrate W in the upper portion of the ring assembly 112. Therefore, by increasing the capacitance of the variable capacitor 51, the heights of the plasma sheath are able to be made substantially the same height between the upper portion of the substrate W and the upper portion of the ring assembly 112. The tilt control is not limited to a case where the ring assembly 112 is worn. Therefore, in FIG. 14, a change in height of the ring assembly 112 itself is also possible. In this way, in the present embodiment, the tilt control is able to be performed at the end portion of the substrate W by changing the capacitance of the impedance adjustment mechanism 50.

### Modification Example 1

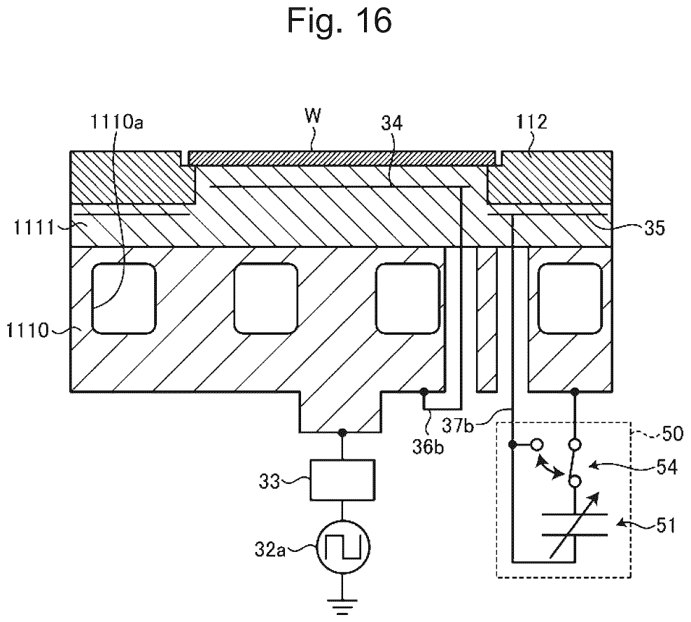

Next, Modification Example 1 will be described with reference to FIG. 16. FIG. 16 is a diagram illustrating an example of an impedance adjustment mechanism in Modification Example 1. As illustrated in FIG. 16, in Modification Example 1, a switch 54 is provided in the impedance adjustment mechanism 50. The switch 54 switches whether the variable capacitor 51 is bypassed. When the switch 54 is switched to bypass the variable capacitor 51, the base 1110 and the second bias electrode 35 are connected to each other. That is, the first DC generator 32a, the matching circuit 33, the base 1110, the switch 54, and the second bias electrode 35 are connected as a circuit (second electrical path of the electrical path 38) on the ring assembly 112 side. In other words, the impedance adjustment mechanism 50 (first impedance adjustment mechanism) includes the switch 54 that bypasses the variable capacitor 51 (first variable capacitor) and connects the base 1110 and the second bias electrode 35. Accordingly, in Modification Example 1, the variable range of the capacitance in the circuit on the ring assembly 112 side is able to be increased.

### Modification Example 2

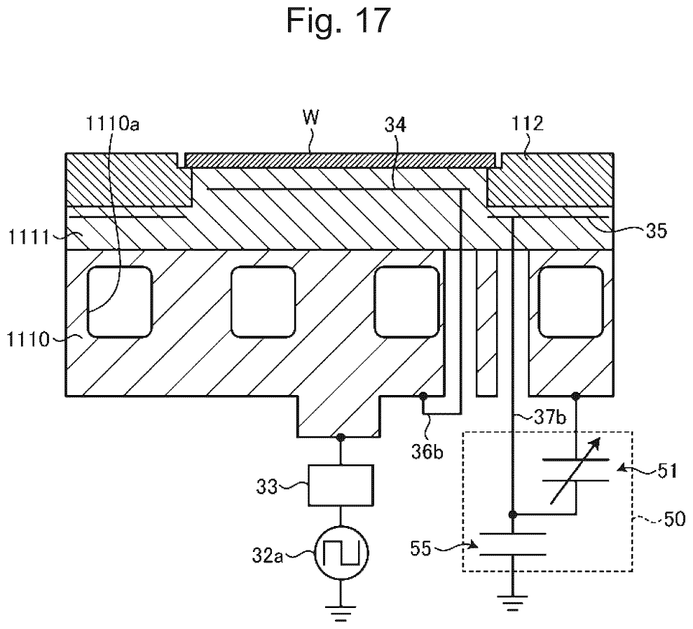

Next, Modification Example 2 will be described with reference to FIG. 17. FIG. 17 is a diagram illustrating an example of an impedance adjustment mechanism in Modification Example 2. As illustrated in FIG. 17, in Modification Example 2, a capacitor 55 is provided in the impedance adjustment mechanism 50. The capacitor 55 is provided to be connected in parallel to a plasma load in order to increase a potential control amount on the ring assembly 112 side. The capacitor 55 may be a fixed-value capacitor or a variable capacitor. In addition, the capacitance of the capacitor 55 is set to a value in a range that does not greatly affect the potential on the ring assembly 112 side, that is, a value in a range in which a fluctuation of the potential as much as in the reference example does not occur. In Modification Example 2, as the circuit (second electrical path of the electrical path 38) on the ring assembly 112 side, the first DC generator 32a, the matching circuit 33, the base 1110, and the variable capacitor 51 are connected in series, and are further connected to the second bias electrode 35 and the capacitor 55 which are connected in parallel. In other words, the impedance adjustment mechanism 50 (first impedance adjustment mechanism) has the capacitor 55 connected in parallel to the plasma load generated in the plasma processing chamber 10 on the second bias electrode 35 side of the variable capacitor 51 (first variable capacitor). Accordingly, in Modification Example 2, the capacitance of the load (the plasma load and the capacitor 55) on the ring assembly 112 side is able to be adjusted. That is, in Modification Example 2, the potential control amount on the ring assembly 112 side is able to be increased according to the capacitance of the capacitor 55.

### Modification Example 3

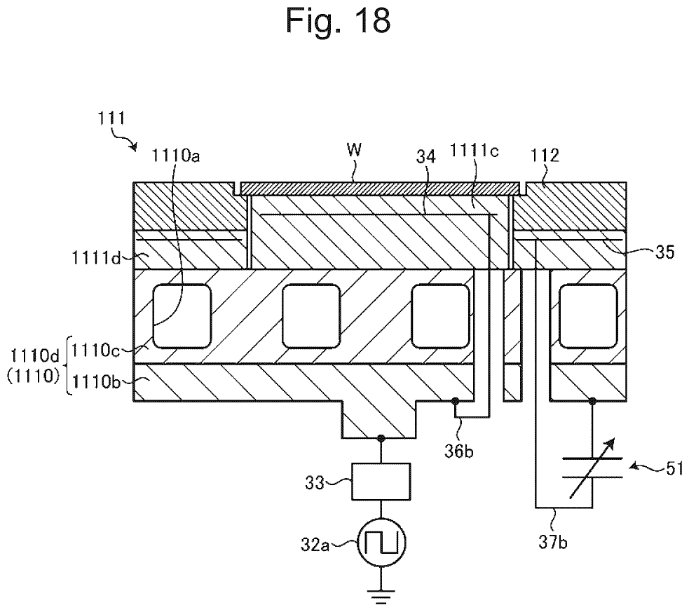

Next, a Modification Example 3 will be described with reference to FIG. 18. FIG. 18 is a diagram illustrating an example of an electrostatic chuck and a base in Modification Example 3. As illustrated in FIG. 18, in Modification Example 3, the main body 111 of the substrate support 11 includes electrostatic chucks 1111c and 1111d instead of the electrostatic chuck 1111. The electrostatic chucks 1111c and 1111d are configured and thus the center region 111a and the annular region 111b of the electrostatic chuck 1111 are respectively separate members. That is, the substrate support 11 of Modification Example 3 is formed and thus the center region 111a (first region) and the annular region 111b (second region) are separate bodies from each other for the electrostatic chucks (electrostatic chucks 1111c and 1111d). That is, the electrostatic chuck 1111c has the center region 111a and has the first bias electrode 34 and the electrostatic electrode 1111b inside. A gap may be provided at a boundary between the electrostatic chuck 1111c and the electrostatic chuck 1111d, or the electrostatic chuck 1111c and the electrostatic chuck 1111d may be in contact with each other. In addition, the electrostatic chuck 1111d has the annular region 111b and has the second bias electrode 35 inside. The electrostatic chuck 1111d may have the electrostatic electrode inside. Further, the base 1110 may be a base 1110d divided into a lower member 1110b and an upper member 1110c (herein “member” means the same as “structure”). The lower member 1110b and the upper member 1110c are formed from, for example, a conductor and are connected to each other in a conductive manner.

In Modification Example 3, as in the present embodiment illustrated in FIGS. 1 and 2, the first bias electrode 34 is connected to, for example, the first DC generator 32a via the conductor 36b, the base 1110 (lower member 1110b), and the matching circuit 33. In addition, the second bias electrode 35 is connected to, for example, the first DC generator 32a via the conductor 37b, the variable capacitor 51, the base 1110 (lower member 1110b), and the matching circuit 33. In Modification Example 3, the electrostatic chucks 1111c and 1111d are configured as separate members, respectively so that deformation due to thermal expansion is able to be absorbed, and manufacturing of the electrostatic chucks 1111c and 1111d is able to be facilitated.

### Modification Example 4

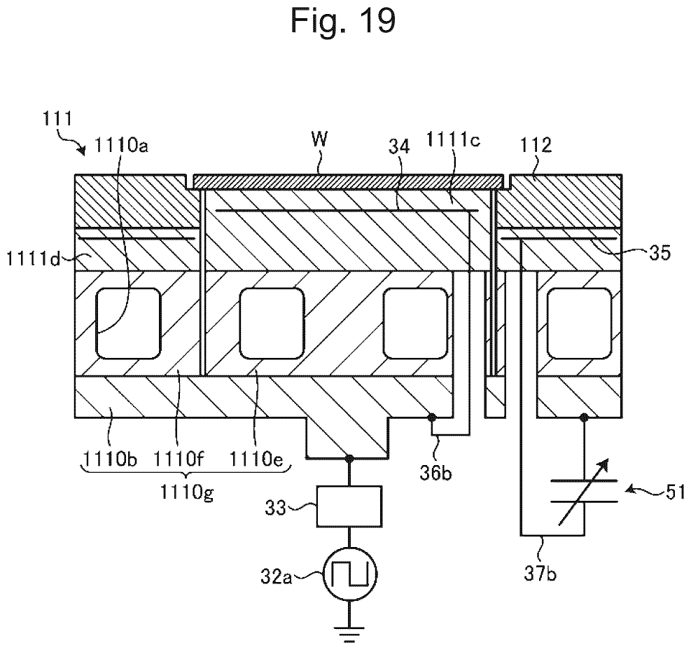

Next, Modification Example 4 will be described with reference to FIG. 19. FIG. 19 is a diagram illustrating an example of an electrostatic chuck and a base in Modification Example 4. As illustrated in FIG. 19, in Modification Example 4, similarly to Modification Example 3, the main body 111 of the substrate support 11 includes the electrostatic chucks 1111c and 1111d instead of the electrostatic chuck 1111. Further, in Modification Example 4, instead of the base 1110, a base 1110g divided into the lower member 1110b, a first upper member 1110e, and a second upper member 1110f is provided. A gap may be provided at a boundary between the first upper member 1110e and the second upper member 1110f, or the first upper member 1110e and the second upper member 1110f may be in contact with each other. For example, the first upper member 1110e and the second upper member 1110f are both formed from a conductor and are connected to the lower member 1110b in a conductive manner. That is, the base 1110g of Modification Example 4 has the first upper member 1110e that supports the first region of the electrostatic chuck, the second upper member 1110f that supports the second region of the electrostatic chuck, and the lower member 1110b that supports the first upper member 1110e and the second upper member 1110f. That is, the first upper member 1110e supports the electrostatic chuck 1111c, and the second upper member 1110f supports the electrostatic chuck 1111d. In addition, the base 1110g is formed and thus the first upper member 1110e, the second upper member 1110f, and the lower member 1110b are respectively separate bodies. In the embodiment and Modification Examples 1 to 3, it is able to be said that the base 1110 is formed and thus the first upper member 1110e, the second upper member 1110f, and the lower member 1110b are integrated with each other.

In Modification Example 4, as in the present embodiment illustrated in FIGS. 1 and 2, the first bias electrode 34 is connected to, for example, the first DC generator 32a via the conductor 36b, the base 1110g (lower member 1110b), and the matching circuit 33. Further, the second bias electrode 35 is connected to, for example, the first DC generator 32a via the conductor 37b, the variable capacitor 51, the base 1110g (lower member 1110b), and the matching circuit 33. In addition, the temperature of each of the first upper member 1110e and the second upper member 1110f may be controlled. In Modification Example 4, the electrostatic chucks 1111c and 1111d, the first upper member 1110e, and the second upper member 1110f are configured as separate members, respectively, and thus the temperature of each of the center region 111a and the annular region 111b is able to be controlled. In addition, manufacturing of the electrostatic chucks 1111c and 1111d, and the base 1110g is able to be facilitated.

In the above-described embodiment, the plasma processing apparatus 1 that performs processing such as etching on the substrate W by using the capacitively coupled plasma as the plasma source is described as an example. However, the technique of the disclosure is not limited thereto. As long as the apparatus performs processing on the substrate W using the plasma, for example, the plasma source is not limited to the capacitively coupled plasma, and any plasma source such as an inductively coupled plasma, a microwave plasma, and a magnetron plasma is able to be used. For example, when the inductively coupled plasma is used, the source RF signal output from the RF power supply is supplied to an antenna disposed on or above the plasma processing chamber so as to form the inductively coupled plasma.

As described above, according to the present embodiment, the plasma processing apparatus 1 includes the chamber (plasma processing chamber 10), the bias power supply (first DC generator 32a) configured to supply the pulsed bias DC signal, the substrate support (substrate support 11) configured to support the substrate W and the edge ring (ring assembly 112) in the chamber, and the electrical path 38. The substrate support is configured to include the electrostatic chuck 1111 that includes the first region (center region 111a) that holds the substrate W, and the second region (annular region 111b) provided around the first region and holding the edge ring, and is formed from a dielectric, the base 1110 supporting the first bias electrode 34 provided inside the first region, the second bias electrode 35 provided inside the second region, and the electrostatic chuck 1111, and the first impedance adjustment mechanism (impedance adjustment mechanism 50) configured to have the first variable capacitor (variable capacitor 51) connected between the second bias electrode 35 and the base 1110. The electrical path 38 has the first electrical path connecting the bias power supply, the base 1110, and the first bias electrode 34, and the second electrical path connecting the bias power supply, the base 1110, the first impedance adjustment mechanism, and the second bias electrode 35. As a result, even when the pulsed DC signal is supplied, the fluctuation of the base potential is able to be suppressed.

In addition, according to the present embodiment, the edge ring, the second region, and the second bias electrode 35 are formed in an annular shape. As a result, fluctuation of the potential of the base is able to be suppressed over an entire circumference of the base 1110.

In addition, according to Modification Example 1, the first impedance adjustment mechanism is configured to include the switch 54 that bypasses the first variable capacitor and connects the base 1110 and the second bias electrode 35 to each other. As a result, the variable range of the capacitance in the circuit on the ring assembly 112 side is able to be increased.

In addition, according to Modification Example 2, the first impedance adjustment mechanism is configured to include the capacitor 55 connected in parallel to the plasma load generated in the chamber on the second bias electrode 35 side of the first variable capacitor. As a result, the potential control amount on the ring assembly 112 side is able to be increased according to the capacitance of the capacitor 55.

In addition, according to the present embodiment, the plasma processing apparatus 1 further includes the second impedance adjustment mechanism configured to have the second variable capacitor connected between the first bias electrode 34 and the base 1110. In addition, the first electrical path connects the bias power supply, the base 1110, the second impedance adjustment mechanism, and the first bias electrode 34. As a result, the potential on the substrate W side is able to be controlled.

In addition, according to the present embodiment and Modification Examples 1 and 2, the substrate support is formed and thus the first region and the second region of the electrostatic chuck 1111 are integrated. As a result, an electrode or wiring that spans the first region and the second region is able to be formed inside the electrostatic chuck 1111.

In addition, according to Modification Examples 3 and 4, the substrate support is formed and thus the first region and the second region of the electrostatic chucks are separate bodies (electrostatic chucks 1111c and 1111d). As a result, deformation due to thermal expansion is able to be absorbed, and the manufacturing of the electrostatic chucks 1111c and 1111d is able to be facilitated.

In addition, according to Modification Example 4, the base 1110g includes the first upper member 1110e that supports the first region of the electrostatic chuck, the second upper member 1110f that supports the second region of the electrostatic chuck, and the lower member 1110b that supports the first upper member 1110e and the second upper member 1110f. As a result, the temperature of each of the center region 111a and the annular region 111b is able to be controlled.

In addition, according to the present embodiment and Modification Examples 1 to 3, the base 1110 is formed and thus the first upper member 1110e, the second upper member 1110f, and the lower member 1110b are integrated. As a result, a degree of freedom in the disposition of the wiring and the piping inside the base 1110 is able to be improved.

In addition, according to Modification Example 4, the base 1110g is formed and thus the first upper member 1110e, the second upper member 1110f, and the lower member 1110b are separate bodies. As a result, the temperature of each of the center region 111a and the annular region 111b is able to be controlled, and the manufacturing of the base 1110 is able to be facilitated.

In addition, according to the present embodiment, the plasma processing apparatus 1 further includes the RF power supply (first RF generator 31a) configured to supply the source RF signal. As a result, the plasma is able to be formed in the plasma processing chamber 10.

In addition, according to the present embodiment, the source RF signal is supplied to at least one lower electrode (base 1110, first bias electrode 34) and/or at least one upper electrode (shower head 13) in the chamber so as to form the capacitively coupled plasma. As a result, the capacitively coupled plasma is able to be formed in the plasma processing chamber 10. In addition, when the source RF signal is supplied to the upper electrode, a ratio of the radicals and the ions in the plasma processing space 10s is able to be adjusted by supplying the source RF signal having a frequency lower than the frequency of the source RF signal on the upper electrode side to the lower electrode.

In addition, according to the present embodiment, the source RF signal is supplied to the antenna disposed on or above the chamber so as to form the inductively coupled plasma. As a result, the inductively coupled plasma is able to be formed in the chamber.

### Example of Another Aspect in Above-Described Embodiment

### Example of Disposing Annular Conductor

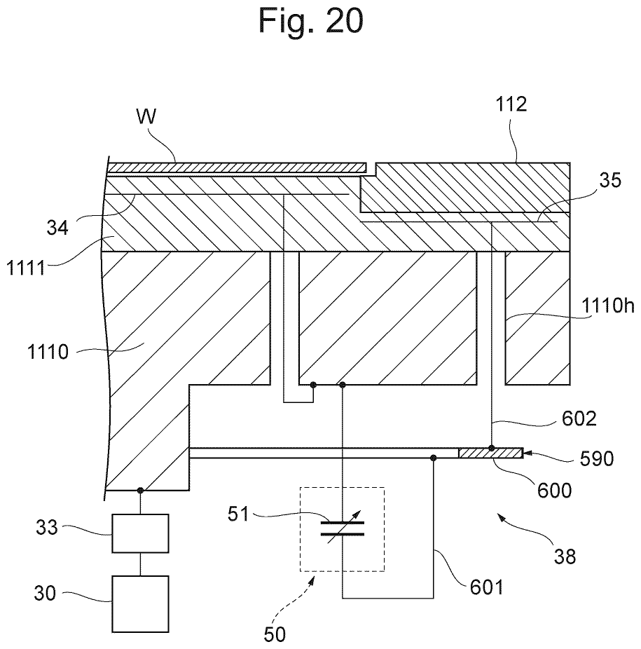

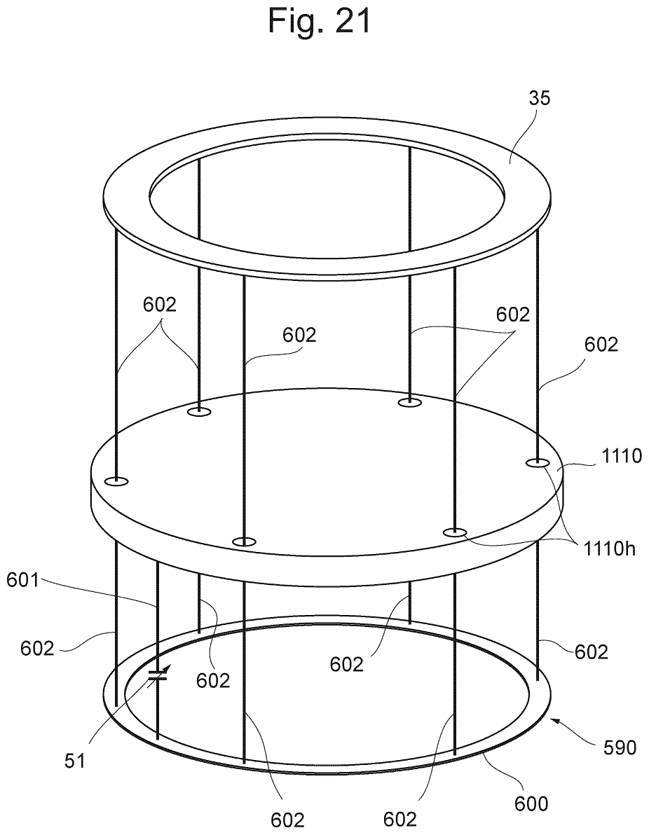

In the above-described embodiment, as illustrated in FIGS. 20 and 21, a second electrical path 590 of the electrical path 38 may include an annular conductor 600 disposed below the base 1110, a first connection conductor 601 that electrically connects the annular conductor 600 and the base 1110 to each other via the first variable capacitor 51 (impedance adjustment mechanism 50), and a plurality of second connection conductors 602 that electrically connect the annular conductor 600 and the second bias electrode 35 in parallel.

The annular conductor 600 is horizontally disposed below the base 1110. The annular conductor 600 is disposed and thus a center of the annular conductor 600 coincides with the center of the base 1110 in plan view. The annular conductor 600 is disposed in parallel with the second bias electrode 35.

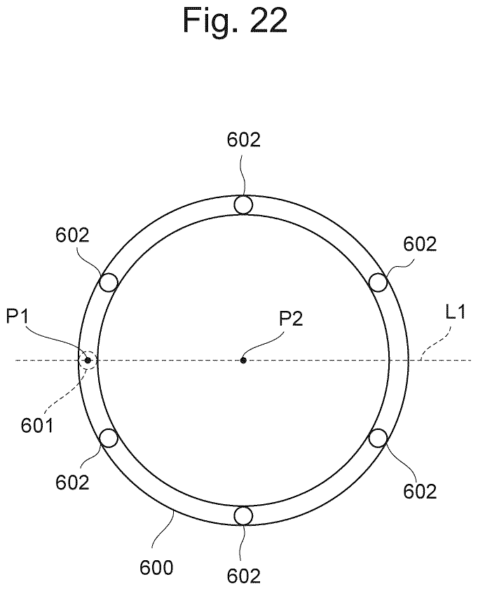

The plurality of second connection conductors 602 are connected in parallel to the annular conductor 600 at equal intervals along a circumferential direction of the annular conductor 600. In an embodiment, as illustrated in FIG. 22, the plurality of second connection conductors 602 are disposed to be linearly symmetrical with respect to a virtual straight line L1 passing through a connection position P1 between the first connection conductor 601 and the annular conductor 600, and a center P2 of the annular conductor 600 in plan view.

As illustrated in FIG. 21, the plurality of second connection conductors 602 are connected in parallel to the second bias electrode 35 at equal intervals along the circumferential direction of the second bias electrode 35. Each of the plurality of second connection conductors 602 may be extended in an up-down direction from the annular conductor 600 toward the second bias electrode 35. Each of the plurality of second connection conductors 602 may be connected to the second bias electrode 35 through a through-hole 1110h of the base 1110.

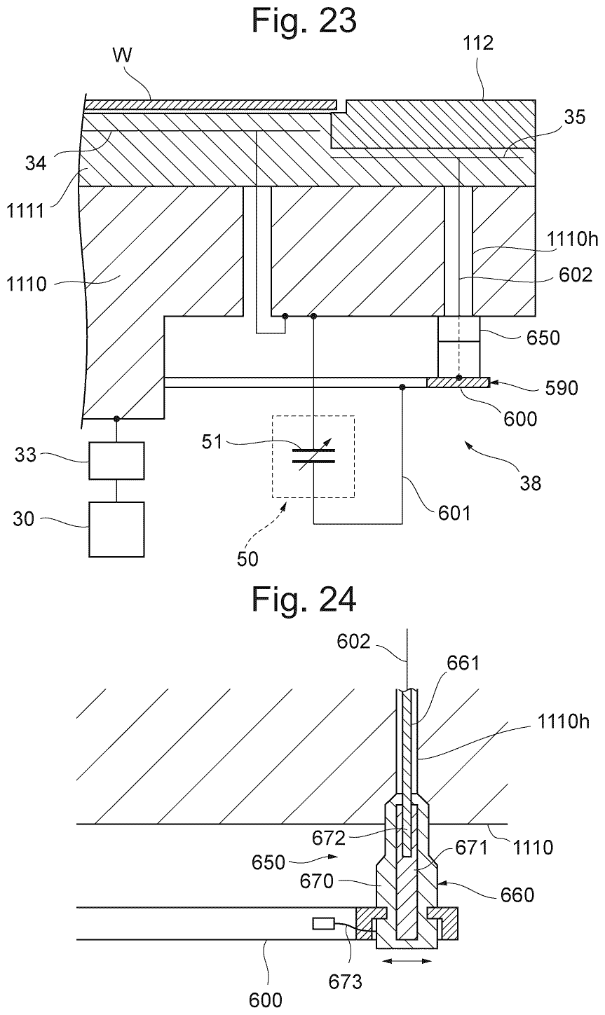

As illustrated in FIG. 23, the plasma processing apparatus 1 may further include a connector 650 for connecting each of the second connection conductors 602 and the annular conductor 600. In an embodiment, the connector 650 is configured to absorb a positional deviation between each of the second connection conductors 602 and the annular conductor 600. The connector 650 is configured to detach and attach each of the second connection conductors 602 and the annular conductor 600.

As illustrated in FIG. 24, the connector 650 may have a fitting structure. In an embodiment, the connector 650 includes a socket 660 erected on the annular conductor 600 and a plug 661 disposed in the second connection conductor 602. The plug 661 extends in the up-down direction, and a lower end portion of the plug 661 protrudes below the base 1110. The socket 660 includes an insulating main body 670 and a conductor portion 671 disposed inside the main body 670. The conductor portion 671 has an insertion hole 672 into which the plug 661 is inserted. The insertion hole 672 extends in the up-down direction. The conductor portion 671 is fitted to the plug 661 and is electrically connected to the plug 661 when the plug 661 is inserted into the insertion hole 672.

The main body 670 of the socket 660 is disposed to move in the horizontal direction to the annular conductor 600. The conductor portion 671 of the socket 660 is electrically connected to the annular conductor 600 by a lead 673. Accordingly, even when the socket 660 is shifted in the horizontal direction to the annular conductor 600, the electrical and physical connection between the socket 660 and the plug 661 is maintained.

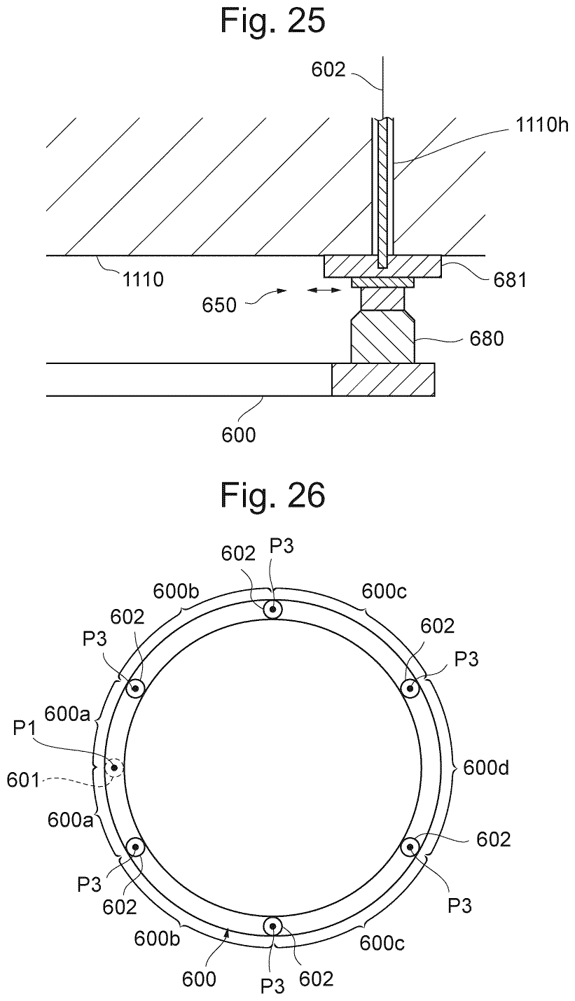

As illustrated in FIG. 25, the connector 650 may have a touch structure. In an embodiment, the connector 650 includes a pressing portion 680 and a receiving portion 681 to which the pressing portion 680 is pressed. The pressing portion 680 is erected on the annular conductor 600. At least an upper end portion of the pressing portion 680 is a conductor and is electrically connected to the annular conductor 600. The upper end portion of the pressing portion 680 may have elasticity that expands and contracts in the up-down direction. The receiving portion 681 is fixed to the lower surface of the base 1110. At least a lower end portion of the receiving portion 681 is a conductor and is electrically connected to the second connection conductor 602. The upper end portion of the pressing portion 680 is pressed against the lower end portion of the receiving portion 681, so that each of the annular conductor 600 and the second connection conductor 602 is able to be electrically and physically connected to each other. An area of the lower end portion of the receiving portion 681 is larger than an area of the upper end portion of the pressing portion 680. Accordingly, even when the pressing portion 680 is shifted in the horizontal direction, the electrical and physical connection between the pressing portion 680 and the receiving portion 681 is maintained.

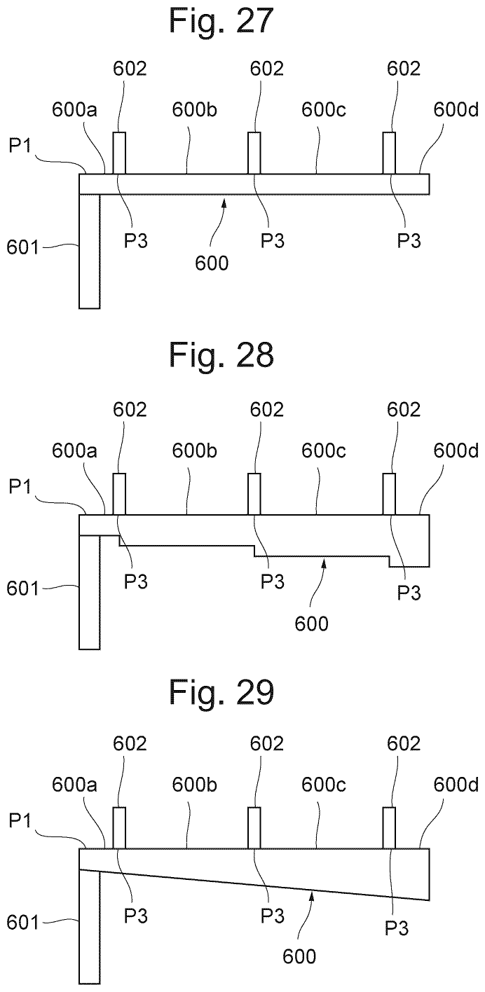

As illustrated in FIGS. 26 and 27, the first connection conductor 601 is connected to a first connection position P1 of the annular conductor 600. The annular conductor 600 has a plurality of, for example, four conductor regions 600a, 600b, 600c, and 600d of which distances from the first connection position P1 are different. That is, the annular conductor 600 includes a first conductor region 600a closest to the first connection position P1, a second conductor region 600b second closest to the first connection position P1, a third conductor region 600c third closest to the first connection position P1, and a fourth conductor region 600d farthest from the first connection position P1. The four conductor regions 600a, 600b, 600c, and 600d may be divided at a connection position P3 at which the plurality of second connection conductors 602 are connected to the annular conductor 600.

The four conductor regions 600a, 600b, 600c, and 600d are configured and thus the electrical resistance decreases as the distance from the first connection position P1 increases. That is, the electrical resistance of the second conductor region 600b is smaller than the electrical resistance of the first conductor region 600a, the electrical resistance of the third conductor region 600c is smaller than the electrical resistance of the second conductor region 600b, and the electrical resistance of the fourth conductor region 600d is smaller than the electrical resistance of the third conductor region 600c. The electrical resistances of the four conductor regions 600a, 600b, 600c, and 600d may be changed by changing the materials of the four conductor regions 600a, 600b, 600c, and 600d. As illustrated in FIG. 28, the electrical resistances of the four conductor regions 600a, 600b, 600c, and 600d may be changed by changing cross-sectional areas (thickness of the annular conductor) of the four conductor regions 600a, 600b, 600c, and 600d. The cross-sectional areas of the four conductor regions 600a, 600b, 600c, and 600d may be changed in a stepwise (discontinuous) manner. As illustrated in FIG. 29, the cross-sectional areas of the four conductor regions 600a, 600b, 600c, and 600d may be continuously changed. Further, the electrical resistance of each of the four conductor regions 600a, 600b, 600c, and 600d may fluctuate within the same conductor region, and may gradually decrease as the distance from the first connection position P1 increases. According to the present exemplary embodiment, it can suppress that a voltage bias in the circumferential direction of the second bias electrode 35 occurs by making the lengths of the plurality of electrical paths from the first connection conductor 601 to the second bias electrode 35 via each of the annular conductor 600 and the plurality of second connection conductors 602 different from each other.

### Example in Which Variable Capacitor Is Disposed in Each of Plurality of Second Connection Conductors

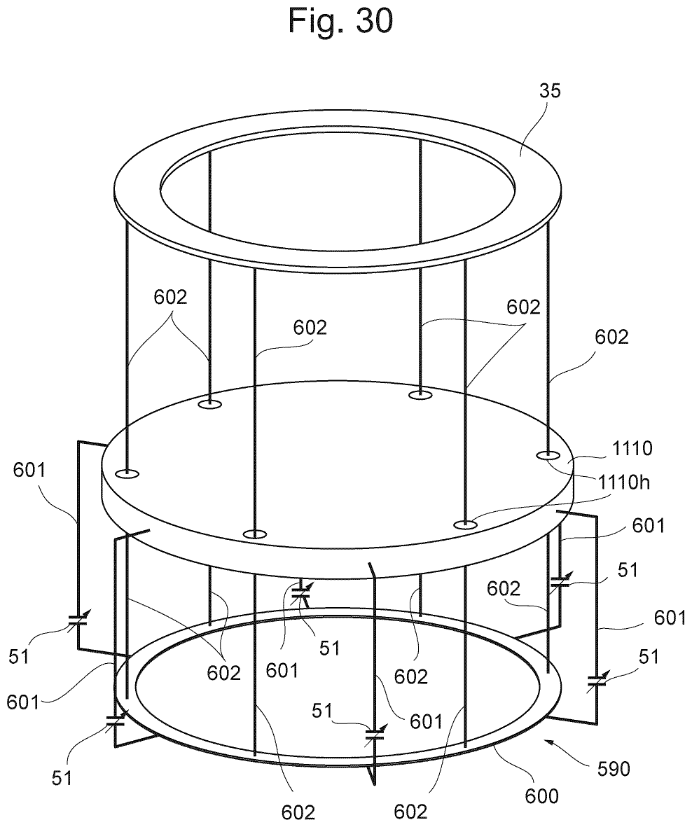

In the above-described embodiment, as illustrated in FIG. 30, a plurality of first connection conductors 601 may be disposed, and the first variable capacitor 51 (impedance adjustment mechanism 50) may be disposed in each of the plurality of first connection conductors 601. That is, the second conductor 221 includes the annular conductor 600 disposed below the base 1110, the plurality of first connection conductors 601 electrically connecting the annular conductor 600 and the base 1110 in parallel, and the plurality of second connection conductors 602 electrically connecting the annular conductor 600 and the second bias electrode 35 in parallel, and the first variable capacitor 51 may be disposed in each of the plurality of first connection conductors 601. The plurality of first connection conductors 601 may be connected in parallel to the annular conductor 600 at equal intervals along the circumferential direction of the annular conductor 600. The plurality of first connection conductors 601 may be connected in parallel to the base 1110 at equal intervals along the circumferential direction of the outer peripheral portion of the base 1110. Other configurations of the second electrical path 590 including the annular conductor 600 and the second connection conductor 602 may be the same as those of the above-described embodiment illustrated in FIGS. 20 to 29. According to the present exemplary embodiment, it can individually adjust the potential of each portion of the ring assembly 112 in the circumferential direction and decrease the potential bias of the ring assembly 112 in the circumferential direction.

### Example in Which Variable Capacitor Is Disposed in Each of Plurality of Connection Conductors

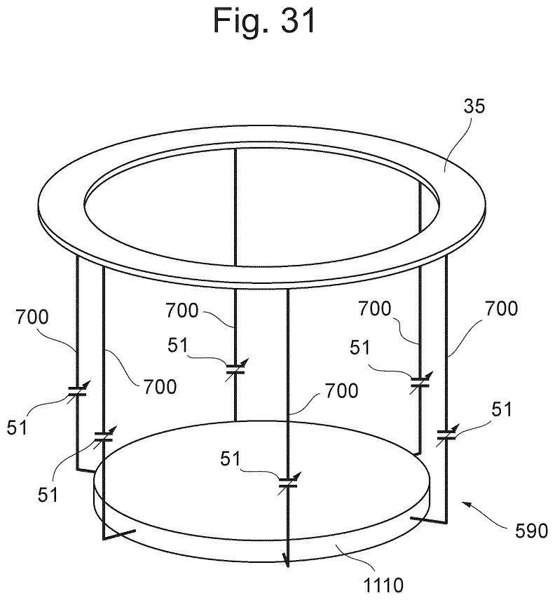

In the above-described embodiment, as illustrated in FIG. 31, the second conductor 221 may include a plurality of connection conductors 700 that electrically connect the base 1110 and the second bias electrode 35 in parallel, and the first variable capacitor 51 (impedance adjustment mechanism 50) may be disposed in each of the plurality of connection conductors 700. The plurality of connection conductors 700 may be connected in parallel to the base 1110 at equal intervals along the circumferential direction of the outer peripheral portion of the base 1110. The plurality of connection conductors 700 may be connected in parallel to the second bias electrode 35 at equal intervals along the circumferential direction of the second bias electrode 35. According to the present exemplary embodiment, it can individually adjust the potential of each portion of the ring assembly 112 in the circumferential direction and decrease the potential bias of the ring assembly 112 in the circumferential direction.

### Configuration Example of Plasma Processing Apparatus When Sensor is Disposed

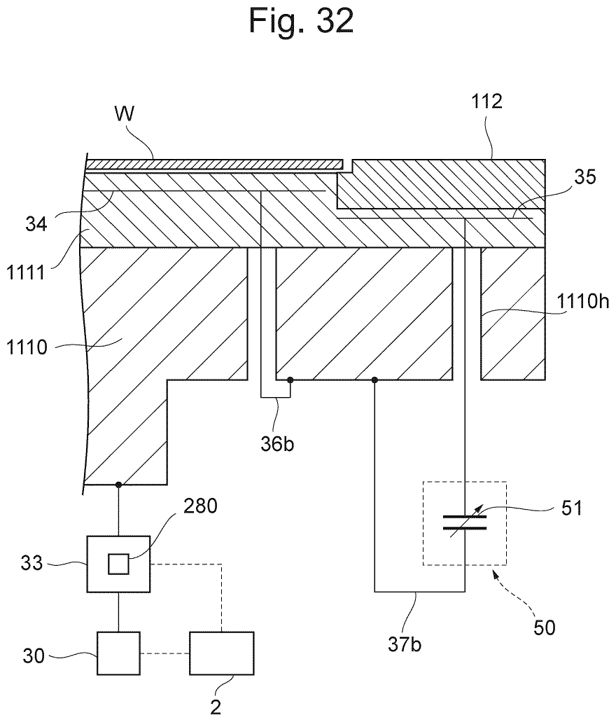

In the above-described embodiment, as illustrated in FIG. 32, the electrical path 38 may have a bias power transfer line 222 that electrically connects the power supply 30 to the base 1110, and the plasma processing apparatus 1 may have a sensor 280 configured to detect a voltage at a given position on the bias power transfer line 222. The controller 2 may be configured to control the supply of the bias signal by the power supply 30 and thus the voltage detected by the sensor 280 becomes constant.

The matching circuit 33 may include the sensor 280. The sensor 280 may be configured to detect the voltage at a position of the matching circuit 33 on the bias power transfer line 222.

In an embodiment, the voltage signal detected by the sensor 280 is output to the controller 2 and is stored in a storage unit. In the controller 2, a program is executed, and the supply of the bias signal from the power supply 30 is feedback-controlled and thus the voltage (voltage of Vpp (voltage peak to peak)) detected by the sensor 280 becomes constant, based on voltage data of the storage unit. According to the present exemplary embodiment, the voltage of the bias signal supplied to the base 1110 is controlled to be constant. Therefore, the voltage of the first bias electrode 34 is stabilized, and the potential of the substrate W is suppressed from fluctuating. As a result, the process fluctuation of the substrate W is suppressed, and the plasma processing is appropriately performed.

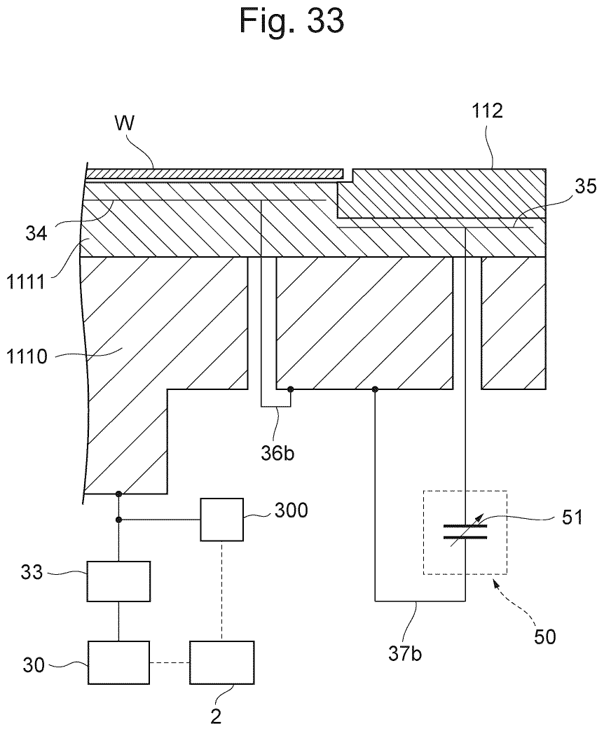

In the above-described embodiment, as illustrated in FIG. 33, the plasma processing apparatus 1 may include a sensor 300 configured to detect a voltage and a current at a given position on the bias power transfer line 222. The controller 2 may be configured to determine the potential of the substrate W on the substrate support 11 based on the voltage and the current detected by the sensor 300, and control the supply of the bias signal by the power supply 30 and thus the potential of the substrate W becomes constant.

The sensor 300 may be electrically connected to a node between the matching circuit 33 on the bias power transfer line 222 and the base 1110. The sensor 300 may be configured to detect the current and the voltage at the node between the matching circuit 33 and the base 1110 on the bias power transfer line 222.

In an embodiment, the voltage signal and the current signal detected by the sensor 300 are output to the controller 2 and are stored in the storage unit. In the controller 2, a program is executed, and the potential of the substrate W on the substrate support 11 is estimated and determined based on the voltage and the current of the bias signal detected by the sensor 300, and a conversion coefficient. Then, in the controller 2, the program is executed, and the supply of the bias signal by the power supply 30 is feedback-controlled and thus the potential (voltage of Vpp (voltage peak to peak)) of the substrate W which is determined becomes constant. The conversion coefficient may be a coefficient obtained in advance and may be used as a coefficient stored in the storage unit of the controller 2. According to the present exemplary embodiment, since the supply of the bias signal by the power supply 30 is controlled and thus the potential of the substrate W is constant, the process fluctuation of the substrate W is suppressed, and the plasma processing is appropriately performed.

### Example of Cleaning Method in Plasma Processing Apparatus

In the above-described embodiment, the controller 2 may be configured to execute (a) plasma processing of the substrate on the substrate support 11 in the chamber 10 and (b) plasma cleaning of the inside of the chamber 10 by adjusting the impedance of the variable impedance element (first variable capacitor 51) to an impedance larger than the impedance in (a). (b) may include at least one of first plasma cleaning performed in a state where the substrate is supported on the substrate support 11 and second plasma cleaning performed in a state where the substrate is not supported on the substrate support 11. The impedance adjustment mechanism 50 may include a capacitor and a switch as a variable impedance element, or may include only a switch.

According to the present exemplary embodiment, in (a), for example, the potential of the ring assembly 112 is able to be adjusted by the first variable capacitor 51, and the plasma sheath 92 on the ring assembly 112 side and the plasma sheath 92 on the substrate W side are able to be brought close to each other horizontally. Accordingly, ions in the plasma enter the outer peripheral portion of the substrate W substantially perpendicularly, and thus the etching rate and the etching shape are able to be improved. In addition, in (b), the impedance of the first variable capacitor 51 is adjusted to be higher than the impedance in (a), and thus the potential of the ring assembly 112 is able to be lowered than the potential of the substrate W or the substrate support surface 210, and the plasma sheath 92 on the ring assembly 112 side is able to be lowered than the substrate W side. Accordingly, the ions in the plasma above the ring assembly 112 are obliquely incident on the outer peripheral portion side of the substrate W, collision of the ions with the ring assembly 112 is suppressed, and the wear of the ring assembly 112 is able to be suppressed. In addition, the ions in the plasma above the ring assembly 112 are able to be caused to collide with the vicinity of the outer peripheral edge of the center region 111a of the substrate support 11, and deposits accumulated in the vicinity of the outer peripheral edge of the center region 111a are able to be removed.

In the above-described embodiment, the impedance adjustment mechanism 50 may have other elements such as a coil, a resistor, and a switch. The impedance adjustment mechanism 50 may have a plurality of variable impedance elements without being limited to one. The variable impedance element of the impedance adjustment mechanism 50 may include at least one type selected from a variable capacitor, a variable resistor, and a variable inductor.

### Other Configuration Examples of Conductive Base

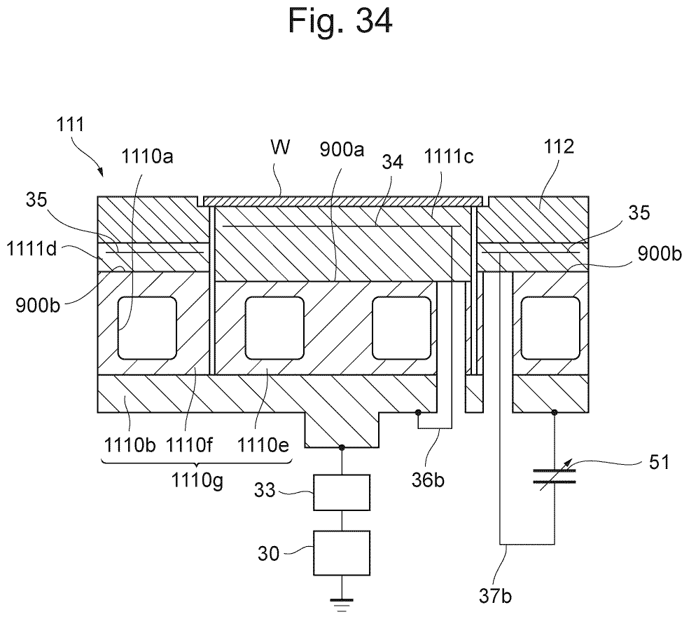

In Modification Example 4, as illustrated in FIG. 34, a height position of an upper surface 900b of the second upper member 1110f may be the same as or higher than a height position of an upper surface 900a of the first upper member 1110e. A height position of a lower surface of the annular region 111b may be higher than the height position of the upper surface of the first upper member 1110e. The height position of the lower surface of the annular region 111b may be higher than the height position of the lower surface of the center region 111a. The flow passage 1110a through which the heat transfer fluid (refrigerant) flows may be disposed in each of the first upper member 1110e and the second upper member 1110f.

### Configuration Example of Circuit Having Capacitor 55

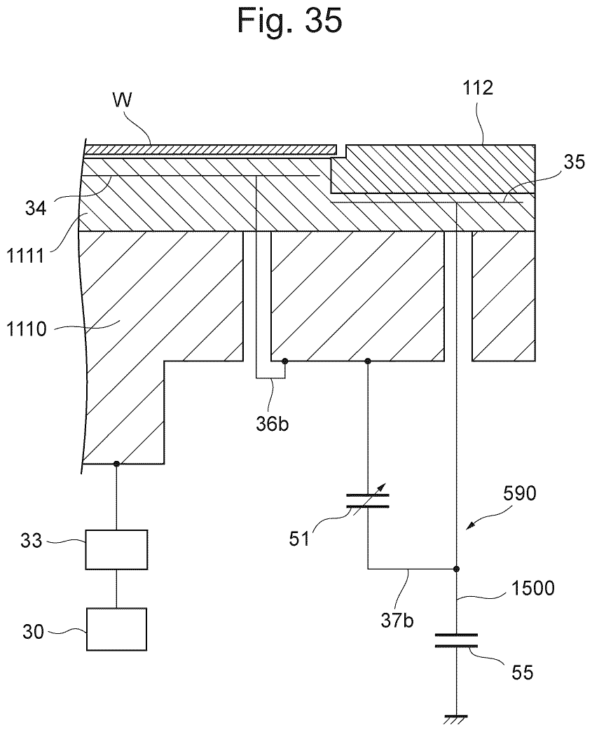

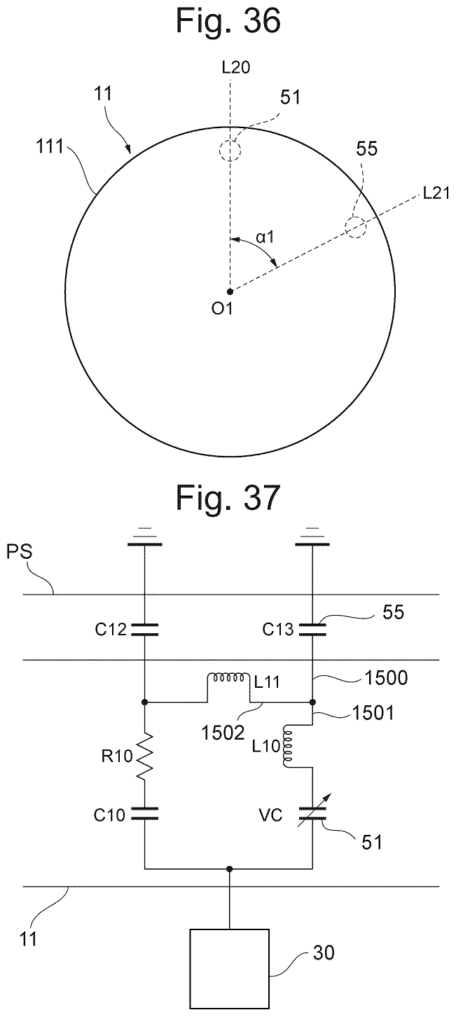

In the above-described embodiment, as in the Modification Example 2, as illustrated in FIG. 35, when the impedance adjustment mechanism 50 has the capacitor 55 electrically connected to the node on the conductor 37b (second electrical path 590) via a conductor 1500, a conductor section 1501 connecting the first variable capacitor 51 and the capacitor 55 may be shortened. In an embodiment, as illustrated in FIG. 36, the first variable capacitor 51 and the capacitor 55 may be disposed and thus an internal angle α1 formed by a virtual straight line L20 passing through the first variable capacitor 51 and a center O1 of the substrate support 11, and a virtual straight line L21 passing through the capacitor 55 and the center O1 is 90° or less in plan view of the substrate support 11.

FIG. 37 is a diagram for describing an electrical circuit formed in a plasma sheath PS of the ring assembly 112 and the substrate support 11 when plasma is formed. In the circuit of the substrate support 11, a capacitance component C10 and a resistance component R10 of the electrostatic chuck 1111 and the first variable capacitor 51 (capacitance VC) are connected in parallel to the power supply 30. In the plasma sheath PS of the ring assembly 112, a capacitance component C12 of the plasma sheath PS and the capacitor 55 (capacitance C13) are connected in parallel to the circuit of the substrate support 11. Here, by bringing the first variable capacitor 51 and the capacitor 55 close to each other, a length of the conductor section 1501 connecting the first variable capacitor 51 and the capacitor 55 is shortened, and a reactance component L10 in the conductor section 1501 is decreased. Accordingly, a reactance component L11 of a conductor section 1502 from the first variable capacitor 51 toward the capacitance component C12 of the plasma sheath increases, and a so-called bridge circuit is formed. As a result, it is suppressed that the parallel resonance occurs between the capacitance component C10 of the electrostatic chuck 1111, the first variable capacitor 51, and the reactance component L10 of the conductor section 1501. As a result, it is suppressed that power loss or an overcurrent occurs by the occurrence of the parallel resonance.

### Other Configuration Examples of Circuit Having Capacitor 55

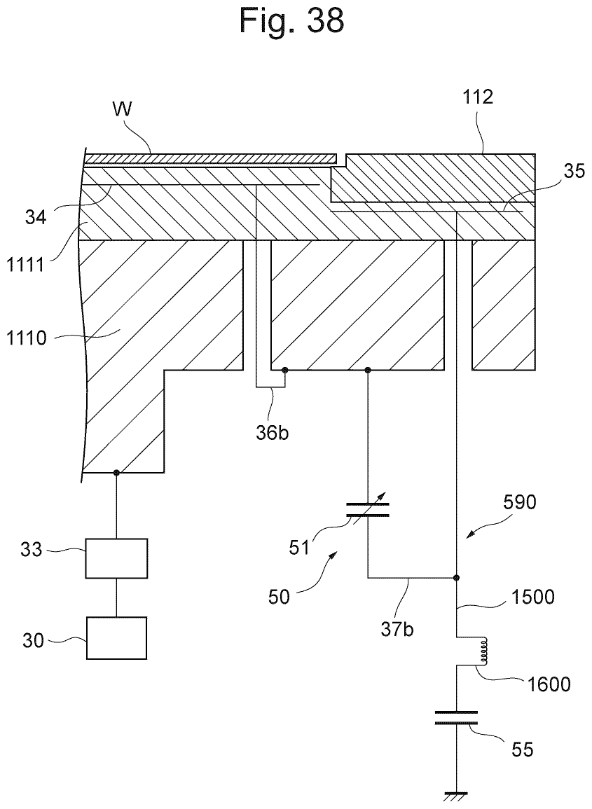

In the above-described embodiment, as illustrated in FIG. 38, a coil 1600 may be connected to the conductor 1500 that connects the node of the conductor 37b (second electrical path 590) to the capacitor 55. Accordingly, when the source RF signal for plasma formation is supplied to the upper electrode, the source RF signal is prevented from entering the ring assembly 112 and the second bias electrode 35, and flowing to the capacitor 55 through the conductor 37b of the impedance adjustment mechanism 50 and the conductor 1500. Accordingly, it can suppress that a plasma distribution in the substrate surface is biased due to the source RF signal locally flowing in a portion (portion above the capacitor 55) where the capacitor 55 is disposed in the circumferential direction of the ring assembly 112. In this example, the source RF signal may be in a range of 1 MHz to 400 MHz.

### Configuration Example of Circuit Including First Variable Capacitor 51

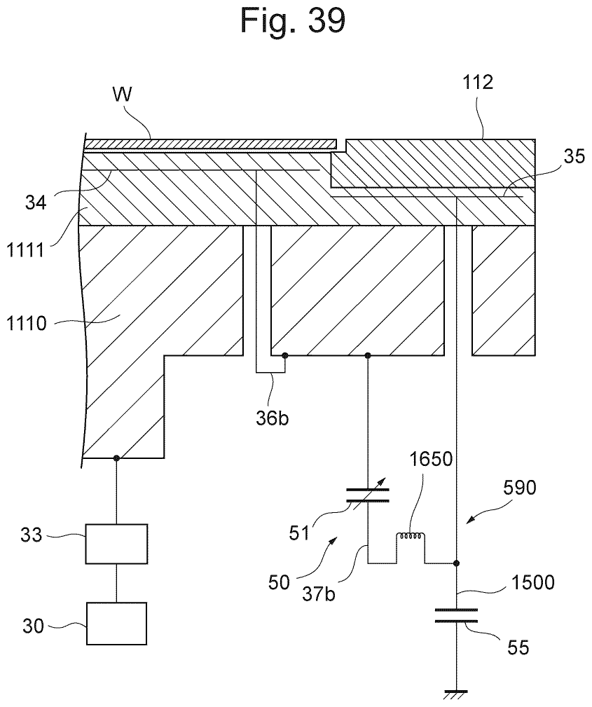

As illustrated in FIG. 39, a coil 1650 may be connected between the first variable capacitor 51 and the second bias electrode 35 in the conductor 37b (second electrical path 590). Accordingly, when the source RF signal for plasma formation is supplied to the upper electrode, the source RF signal is prevented from entering the ring assembly 112 and the second bias electrode 35, and flowing to the first variable capacitor 51 through the conductor 37b of the impedance adjustment mechanism 50. Accordingly, it can suppress that the plasma distribution in the substrate surface is biased due to the source RF signal locally flowing in a portion (portion above the first variable capacitor 51) where the first variable capacitor 51 is disposed in the circumferential direction of the ring assembly 112.

### Other Configuration Examples of Circuit Including First Variable Capacitor 51

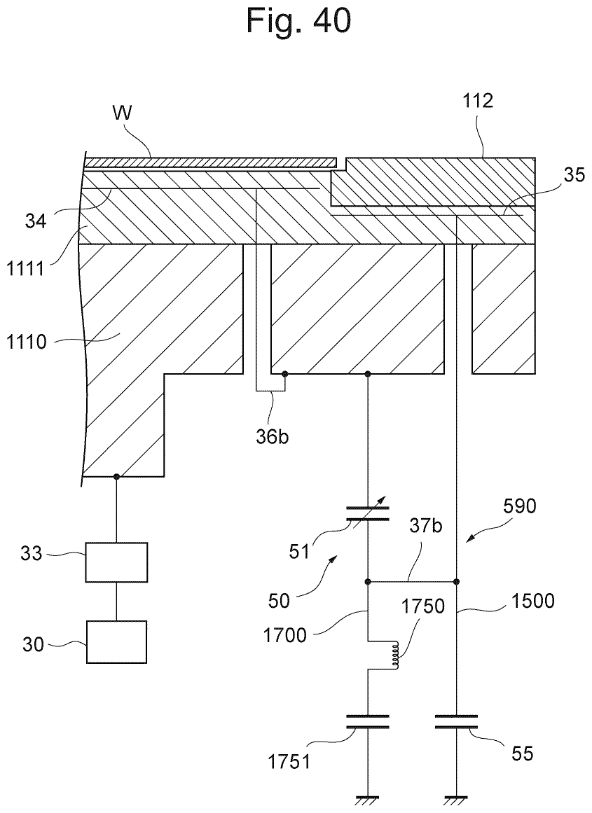

As illustrated in FIG. 40, a coil 1750 electrically connected to the node on the conductor 37b via a conductor 1700 may be disposed. The conductor 1700 is connected to the node between the first variable capacitor 51 and the second bias electrode 35 in the conductor 37b. The coil 1750 is connected to a ground potential. In this way, a parallel resonance circuit is configured with a stray capacitance of the first variable capacitor 51 and the coil 1750, and the source RF signal is prevented from entering the ring assembly 112 and the second bias electrode 35, and flowing to the first variable capacitor 51 through the conductor 37b of the impedance adjustment mechanism 50. Furthermore, a capacitor 1751 is connected in series to the conductor 1700 in addition to the coil 1750. The capacitor 1751 is connected to the ground potential. Accordingly, the LC series circuit is formed in the conductor 1700, and the bias signal supplied to the lower electrode is suppressed from flowing to the ground potential through the conductor 1700.

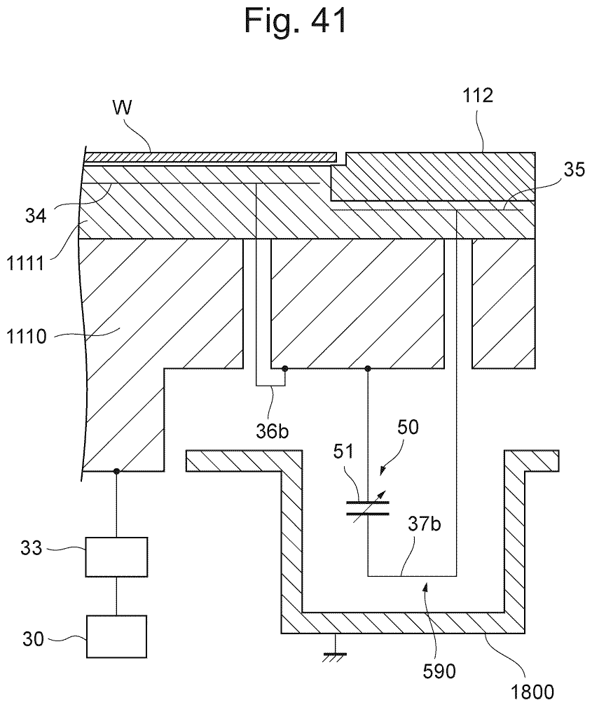

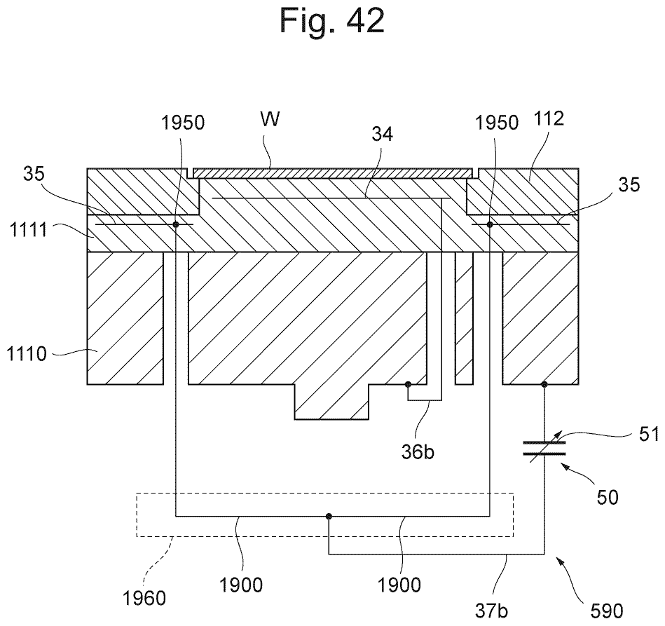

As illustrated in FIG. 41, the stray capacitance between the conductor 37b and a ground case 1800 surrounding the conductor 37b may be decreased. That is, a distance between the conductor 37b and the ground case 1800 may be as large as possible. In an embodiment, the conductor 37b and the ground case 1800 may be separated from each other by 2 cm or more. In this way, the source RF signal is prevented from entering the ring assembly 112 and the second bias electrode 35, and flowing to the first variable capacitor 51 through the conductor 37b of the impedance adjustment mechanism 50.

### Configuration Example of Circuit between First Variable Capacitor 51 And Second Bias Electrode 35

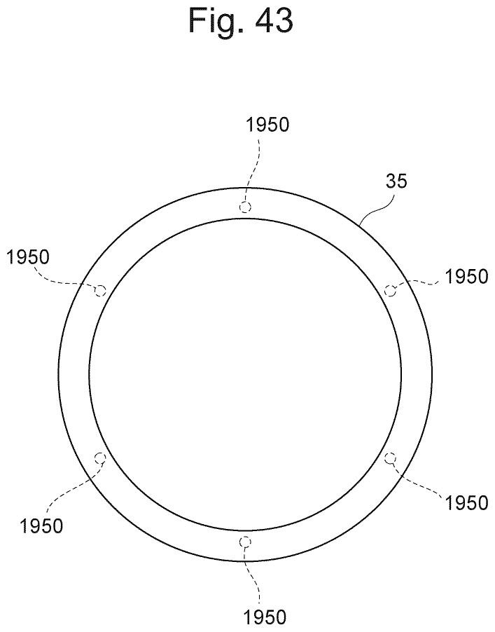

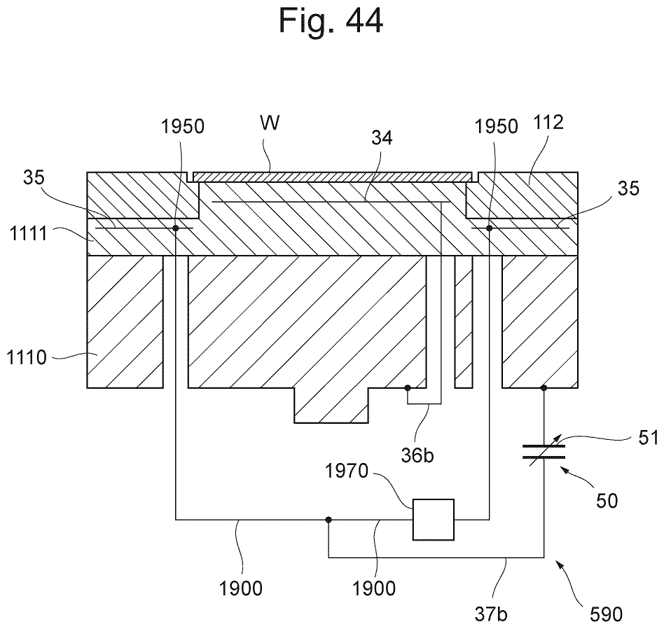

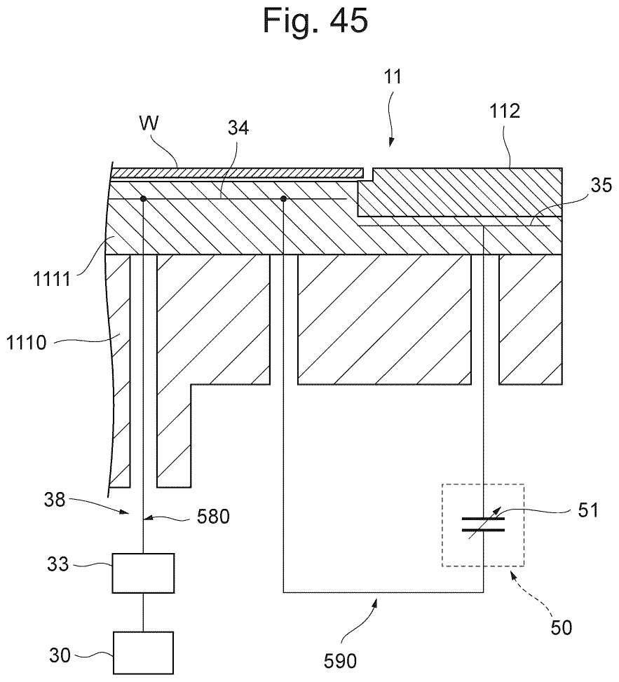

As illustrated in FIG. 42, the conductor 37b (second electrical path 590) includes a plurality of connection conductors 1900 that electrically connect the first variable capacitor 51 and the second bias electrode 35 in parallel. As illustrated in FIG. 43, connection points 1950 to which each of the plurality of connection conductors 1900 is connected in the second bias electrode 35 are disposed at equal intervals along the circumferential direction of the second bias electrode 35. The plurality of connection conductors 1900 are adjusted to have substantially equal impedances. In an embodiment, as illustrated in FIG. 42, the impedances of the plurality of connection conductors 1900 may be adjusted by making a path length from the first variable capacitor 51 to the second bias electrode 35 equal. In this case, the plurality of connection conductors 1900 may be formed on a printed circuit board 1960, and path lengths may be aligned. The printed circuit board 1960 may be disposed below the base 1110. In an embodiment, as illustrated in FIG. 44, the impedances of the plurality of connection conductors 1900 may be adjusted by adding an impedance element 1970 to at least one of the plurality of connection conductors 1900. The impedance element 1970 may be a coil, a capacitor, a resistor, or a combination thereof. The impedances of the plurality of connection conductors 1900 may be adjusted by changing at least one material of the plurality of connection conductors 1900. The impedances of the plurality of connection conductors 1900 may be aligned by other methods.

Accordingly, the source RF signal for plasma formation is supplied to the upper electrode, and when the source RF signal enters the plurality of connection conductors 1900 via the ring assembly 112 and the connection point 1950 of the second bias electrode 35, the currents flowing through the plurality of connection conductors 1900 are aligned. As a result, it can suppress that the plasma distribution in the substrate surface is biased due to a relatively large current flowing through a specific connection conductor 1900.

### Other Configuration Examples of Electrical Path

In an embodiment, as illustrated in FIG. 45, the substrate support 11 may be configured to include the electrostatic chuck 1111 including the first region (center region 111a) that holds the substrate W, the second region (annular region 111b) provided around the first region and holding the edge ring, and formed from the dielectric, the base 1110 that supports the first bias electrode 34 provided inside the first region, the second bias electrode 35 provided inside the second region, and the electrostatic chuck 1111, and the first impedance adjustment mechanism (impedance adjustment mechanism 50) configured to include the first variable capacitor (variable capacitor 51) connected between the second bias electrode 35 and the first bias electrode 34. The electrical path 38 may include a first electrical path 580 that connects the bias power supply and the first bias electrode 34, and a second electrical path 590 that connects the bias power supply, the first bias electrode 34, the first impedance adjustment mechanism, and the second bias electrode 35. That is, the bias power supply is directly connected to the first bias electrode 34 instead of the base 1110, and the second bias electrode 35 is connected to the first bias electrode 34 instead of the base 1110. The first impedance adjustment mechanism is connected to an electrical path between the second bias electrode 35 and the first bias electrode 34. Other configurations of the present embodiment may be the same as those of the above-described embodiment. According to the present embodiment, even when the pulsed DC signal is supplied, it can suppress the fluctuation of the base potential. In the present embodiment, all aspects described in the above-described embodiments may be applied.

### Other Configuration Examples of Electrical Path

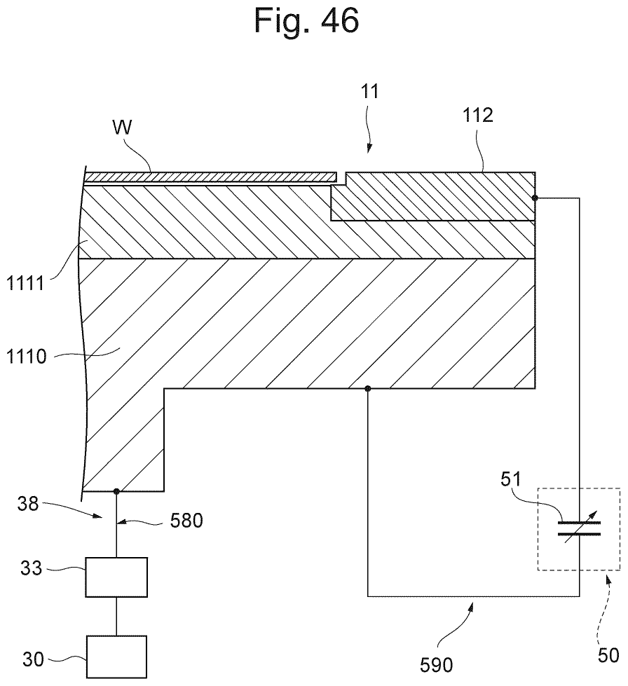

In an embodiment, as illustrated in FIG. 46, the substrate support 11 may be configured to include the electrostatic chuck 1111 including the first region (center region 111a) holding the substrate W and the second region (annular region 111b) provided around the first region and holding the edge ring, formed from the dielectric, the base 1110 that supports the electrostatic chuck 1111, and the first impedance adjustment mechanism (impedance adjustment mechanism 50) configured to include the first variable capacitor (variable capacitor 51) connected between the base 1110 and the ring assembly 112. The electrical path 38 may have the first electrical path connecting the bias power supply and the base 1110, and the second electrical path connecting the bias power supply, the base 1110, the first impedance adjustment mechanism, and the ring assembly 112. That is, the bias power supply is connected to the base 1110 instead of the first bias electrode 34. The first impedance adjustment mechanism is connected to the edge ring instead of the second bias electrode 35. Other configurations of the present embodiment may be the same as those of the above-described embodiment. According to the present embodiment, even when the pulsed DC signal is supplied, it can suppress the fluctuation of the base potential. In the present embodiment, all aspects described in the above-described embodiments may be applied.

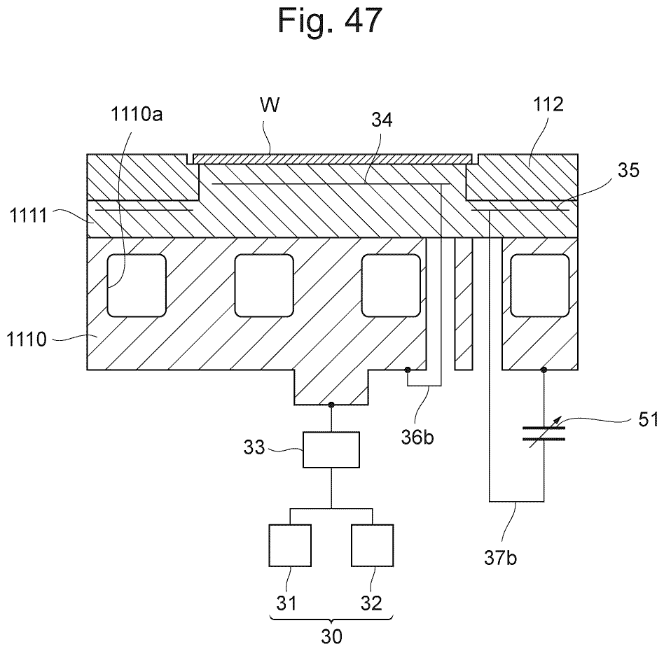

In the above-described embodiment, the power supply 30 may be configured to supply both the RF signal and the pulsed voltage signal to the base 1110 as the bias signal. That is, in the above-described embodiment, as illustrated in FIG. 47, the power supply 30 may include the RF power supply 31 configured to supply the bias RF signal and the DC power supply 32 configured to supply the bias DC signal. The frequency of the RF signal supplied by the power supply 30 may be a frequency in a range of 100 kHz to 60 MHz. The pulsed voltage signal supplied by the power supply 30 may have a sequence of a plurality of voltage pulses. The frequency of the voltage pulse may be 400 kHz. The frequency of the voltage pulse may be any frequency in a range of 200 kHz to 3 MHz. In addition, the duty ratio of the voltage pulse may be 20% or more than 20%.

In the above-described embodiment, the source power supply of the plasma generator may supply the source RF signal to any one of the upper electrode (for example, the shower head) or the lower electrode (for example, the conductive base).

The present disclosure is able to also adopt the following configurations.
(1)

A plasma processing apparatus including:
a chamber;
a bias power supply configured to supply a pulsed bias DC signal;
a substrate support configured to support a substrate and an edge ring in the chamber; and
an electrical path,
in which the substrate support includes
   an electrostatic chuck including a first region configured to hold the substrate and a second region configured to hold the edge ring, the second region provided around the first region, and the electrostatic chuck formed from a dielectric,
   a first bias electrode provided inside the first region,
   a second bias electrode provided inside the second region,
   a base configured to support the electrostatic chuck, and
   a first impedance adjustment mechanism configured to have a first variable capacitor connected between the second bias electrode and the base, and
the electrical path includes
   a first electrical path configured to connect the bias power supply, the base, and the first bias electrode, and
   a second electrical path configured to connect the bias power supply, the base, the first impedance adjustment mechanism, and the second bias electrode.
(2)

The plasma processing apparatus according to (1), in which the edge ring, the second region, and the second bias electrode are formed in an annular shape.
(3)

The plasma processing apparatus according to (1) or (2), in which the first impedance adjustment mechanism is configured to have a switch that bypasses the first variable capacitor and connects the base and the second bias electrode.
(4)

The plasma processing apparatus according to (1) or (2), in which the first impedance adjustment mechanism is configured to have a capacitor connected in parallel to a plasma load generated inside the chamber on a second bias electrode side of the first variable capacitor.
(5)

The plasma processing apparatus according to any one of (1) to (4), further including:
a second impedance adjustment mechanism configured to have a second variable capacitor connected between the first bias electrode and the base,
in which the first electrical path connects the bias power supply, the base, the second impedance adjustment mechanism, and the first bias electrode.
(6)

The plasma processing apparatus according to any one of (1) to (5), in which the substrate support is formed with the first region and the second region of the electrostatic chuck being integrated with each other.
(7)

The plasma processing apparatus according to any one of (1) to (5), in which the substrate support is formed with the first region and the second region of the electrostatic chuck being separate bodies.
(8)

The plasma processing apparatus according to (7), in which the base has a first upper member configured to support the first region of the electrostatic chuck, a second upper member configured to support the second region of the electrostatic chuck, and a lower member configured to support the first upper member and the second upper member.
(9)

The plasma processing apparatus according to (8), in which the base is formed and thus the first upper member, the second upper member, and the lower member are integrated.
(10)

The plasma processing apparatus according to (9), in which the base is formed with the first upper member, the second upper member, and the lower member being separate bodies.
(11)

The plasma processing apparatus according to any one of (1) to (10), further including:
an RF power supply configured to supply a source RF signal.
(12)

The plasma processing apparatus according to (11), in which the source RF signal is supplied to at least one lower electrode and/or at least one upper electrode in the chamber to form a capacitively coupled plasma.
(13)

The plasma processing apparatus according to (11), in which the source RF signal is supplied to an antenna disposed on or above the chamber to form an inductively coupled plasma.
(14)

The plasma processing apparatus according to any one of (1) to (13), in which the second electrical path includes:
an annular conductor disposed below the base,
a first connection conductor configured to electrically connect the annular conductor and the base via the first variable capacitor, and
a plurality of second connection conductors configured to electrically connect the annular conductor and the second bias electrode in parallel.
(15)

The plasma processing apparatus according to (14), in which the plurality of second connection conductors are connected in parallel to the annular conductor at equal intervals along a circumferential direction of the annular conductor.
(16)

The plasma processing apparatus according to (14) or (15), in which the plurality of second connection conductors are connected in parallel to the second bias electrode at equal intervals along a circumferential direction of the second bias electrode.
(17)

The plasma processing apparatus according to any one of (14) to (16), further including:
a connector configured to connect each of the second connection conductors and the annular conductor.
(18)

The plasma processing apparatus according to (17), in which the connector is configured to absorb a positional deviation between each of the second connection conductors and the annular conductor.
(19)

The plasma processing apparatus according to any one of (14) to (18),
in which the first connection conductor is connected to a first connection position of the annular conductor,
the annular conductor includes a plurality of conductor regions having different distances from the first connection position, and
the plurality of conductor regions are configured to have smaller electrical resistance as a distance from the first connection position increases.
(20)

The plasma processing apparatus according to any one of (1) to (13), in which the second electrical path includes:
an annular conductor disposed below the base,
a plurality of first connection conductors configured to electrically connect the annular conductor and the base in parallel, and
a plurality of second connection conductors configured to electrically connect the annular conductor and the second bias electrode in parallel, and
the first impedance adjustment mechanism is disposed in each of the plurality of first connection conductors.
(21)

The plasma processing apparatus according to (20), in which the plurality of first connection conductors are connected in parallel at equal intervals along a circumferential direction of the annular conductor with respect to the annular conductor.
(22)

The plasma processing apparatus according to any one of (1) to (13),
in which the second electrical path includes a plurality of connection conductors configured to electrically connect the base and the second bias electrode in parallel, and
the first impedance adjustment mechanism is disposed in each of the plurality of connection conductors.
(23)

The plasma processing apparatus according to (22), in which the plurality of connection conductors are connected in parallel to the second bias electrode at equal intervals along a circumferential direction of the second bias electrode.
(24)

The plasma processing apparatus according to any one of (1) to (23), further including:
an RF power supply configured to supply an RF bias signal to the base.
(25)

A substrate support configured to support a substrate and an edge ring in a chamber of a plasma processing apparatus, the substrate support including:
an electrostatic chuck including a first region configured to hold the substrate and a second region configured to hold the edge ring, the second region provided around the first region, and the electrostatic chuck formed from a dielectric;
a first bias electrode provided inside the first region;
a second bias electrode provided inside the second region;
a base configured to support the electrostatic chuck;
an impedance adjustment mechanism configured to have a variable capacitor connected between the second bias electrode and the base;
a first electrical path connecting the base connected to a bias power supply configured to supply a pulsed bias DC signal and the first bias electrode; and
a second electrical path connecting the base connected to the bias power supply, the impedance adjustment mechanism, and the second bias electrode.
(26)

A plasma processing apparatus including:
a chamber;
a bias power supply configured to supply a pulsed bias DC signal;
a substrate support configured to support a substrate and an edge ring in the chamber; and
an electrical path,
in which the substrate support includes
   an electrostatic chuck including a first region configured to hold the substrate and a second region configured to hold the edge ring, the second region provided around the first region, and the electrostatic chuck formed from a dielectric,
   a first bias electrode provided inside the first region,
   a second bias electrode provided inside the second region,
   a base configured to support the electrostatic chuck, and
   a first impedance adjustment mechanism configured to have a first variable capacitor connected between the second bias electrode and the first bias electrode, and
the electrical path includes
   a first electrical path configured to connect the bias power supply and the first bias electrode, and
   a second electrical path configured to connect the bias power supply, the first bias electrode, the first impedance adjustment mechanism, and the second bias electrode.
(27)

The plasma processing apparatus according to (26), in which the edge ring, the second region, and the second bias electrode are formed in an annular shape.
(28)

The plasma processing apparatus according to (26) or (27), in which the first impedance adjustment mechanism is configured to have a switch that bypasses the first variable capacitor and connects the first bias electrode and the second bias electrode.
(29)

The plasma processing apparatus according to (26) or (27), in which the first impedance adjustment mechanism is configured to have a capacitor connected in parallel to a plasma load generated inside the chamber on a second bias electrode side of the first variable capacitor.
(30)

The plasma processing apparatus according to any one of (26) to (29), further including:
a second impedance adjustment mechanism configured to have a second variable capacitor connected between the bias power supply and the first bias electrode,
in which the first electrical path connects the bias power supply, the second impedance adjustment mechanism, and the first bias electrode.
(31)

The plasma processing apparatus according to any one of (26) to (30), in which the substrate support is formed with the first region and the second region of the electrostatic chuck being integrated with each other.
(32)

The plasma processing apparatus according to any one of (26) to (30), in which the substrate support is formed with the first region and the second region of the electrostatic chuck being separate bodies.
(33)

The plasma processing apparatus according to (32), in which the base has a first upper member configured to support the first region of the electrostatic chuck, a second upper member configured to support the second region of the electrostatic chuck, and a lower member configured to support the first upper member and the second upper member.
(34)

The plasma processing apparatus according to (33), in which the base is formed and thus the first upper member, the second upper member, and the lower member are integrated.
(35)

The plasma processing apparatus according to (34), in which the base is formed with the first upper member, the second upper member, and the lower member being separate bodies.
(36)

The plasma processing apparatus according to any one of (26) to (35), further including:
an RF power supply configured to supply a source RF signal.
(37)

The plasma processing apparatus according to (36), in which the source RF signal is supplied to at least one lower electrode and/or at least one upper electrode in the chamber to form a capacitively coupled plasma.
(38)

The plasma processing apparatus according to (36), in which the source RF signal is supplied to an antenna disposed on or above the chamber to form an inductively coupled plasma.
(39)

The plasma processing apparatus according to any one of (26) to (38), in which the second electrical path includes:
an annular conductor disposed below the base,
a first connection conductor configured to electrically connect the annular conductor and the first bias electrode via the first variable capacitor, and
a plurality of second connection conductors configured to electrically connect the annular conductor and the second bias electrode in parallel.
(40)

The plasma processing apparatus according to (39), in which the plurality of second connection conductors are connected in parallel to the annular conductor at equal intervals along a circumferential direction of the annular conductor.
(41)

The plasma processing apparatus according to (39) or (40), in which the plurality of second connection conductors are connected in parallel to the second bias electrode at equal intervals along a circumferential direction of the second bias electrode.
(42)

The plasma processing apparatus according to any one of (39) to (41), further including:
a connector configured to connect each of the second connection conductors and the annular conductor.
(43)

The plasma processing apparatus according to (42), in which the connector is configured to absorb a positional deviation between each of the second connection conductors and the annular conductor.
(44)

The plasma processing apparatus according to any one of (39) to (43),
in which the first connection conductor is connected to a first connection position of the annular conductor,
the annular conductor includes a plurality of conductor regions having different distances from the first connection position, and
the plurality of conductor regions are configured to have smaller electrical resistance as a distance from the first connection position increases.
(45)

The plasma processing apparatus according to any one of (26) to (38), in which the second electrical path includes:
an annular conductor disposed below the base,
a plurality of first connection conductors configured to electrically connect the annular conductor and the first bias electrode in parallel, and
a plurality of second connection conductors configured to electrically connect the annular conductor and the second bias electrode in parallel, and
the first impedance adjustment mechanism is disposed in each of the plurality of first connection conductors.
(46)

The plasma processing apparatus according to (45), in which the plurality of first connection conductors are connected in parallel at equal intervals along a circumferential direction of the annular conductor with respect to the annular conductor.
(47)

The plasma processing apparatus according to any one of (26) to (38),
in which the second electrical path includes a plurality of connection conductors that electrically connect the first bias electrode and the second bias electrode in parallel, and
the first impedance adjustment mechanism is disposed in each of the plurality of connection conductors.
(48)

The plasma processing apparatus according to (47), in which the plurality of connection conductors are connected in parallel to the second bias electrode at equal intervals along a circumferential direction of the second bias electrode.
(49)

The plasma processing apparatus according to any one of (26) to (48), further including:
an RF power supply configured to supply an RF bias signal to the first bias electrode.
(50)

A plasma processing apparatus including:
a chamber;
a bias power supply configured to supply a pulsed bias DC signal;
a substrate support configured to support a substrate and an edge ring in the chamber; and
an electrical path,
in which the substrate support includes
   an electrostatic chuck including a first region configured to hold the substrate and a second region configured to hold the edge ring, the second region provided around the first region, and the electrostatic chuck formed from a dielectric,
   a base configured to support the electrostatic chuck, and
   a first impedance adjustment mechanism configured to have a first variable capacitor connected between the base and the edge ring, and
the electrical path includes
   a first electrical path configured to connect the bias power supply and the base, and
   a second electrical path configured to connect the bias power supply, the base, the first impedance adjustment mechanism, and the edge ring.
(51)

The plasma processing apparatus according to (50), in which the edge ring and the second region are formed in an annular shape.
(52)

The plasma processing apparatus according to (50) or (51), in which the first impedance adjustment mechanism is configured to have a switch that bypasses the first variable capacitor and connects the base and the edge ring.
(53)

The plasma processing apparatus according to (50) or (51), in which the first impedance adjustment mechanism is configured to have a capacitor connected in parallel to a plasma load generated inside the chamber on the edge ring side of the first variable capacitor.
(54)

The plasma processing apparatus according to any one of (50) to (53), further including:
a second impedance adjustment mechanism configured to have a second variable capacitor connected between the bias power supply and the base,
in which the first electrical path connects the bias power supply, the second impedance adjustment mechanism, and the base.
(55)

The plasma processing apparatus according to any one of (50) to (54), in which the substrate support is formed with the first region and the second region of the electrostatic chuck being integrated with each other.
(56)

The plasma processing apparatus according to any one of (50) to (54), in which the substrate support is formed with the first region and the second region of the electrostatic chuck being separate bodies.
(57)

The plasma processing apparatus according to (56), in which the base has a first upper member configured to support the first region of the electrostatic chuck, a second upper member configured to support the second region of the electrostatic chuck, and a lower member configured to support the first upper member and the second upper member.
(58)

The plasma processing apparatus according to (57), in which the base is formed and thus the first upper member, the second upper member, and the lower member are integrated.
(59)

The plasma processing apparatus according to (58), in which the base is formed with the first upper member, the second upper member, and the lower member being separate bodies.
(60)

The plasma processing apparatus according to any one of (50) to (59), further including:
an RF power supply configured to supply a source RF signal.
(61)

The plasma processing apparatus according to (60), in which the source RF signal is supplied to at least one lower electrode and/or at least one upper electrode in the chamber to form a capacitively coupled plasma.
(62)

The plasma processing apparatus according to (60), in which the source RF signal is supplied to an antenna disposed on or above the chamber to form an inductively coupled plasma.
(63)

The plasma processing apparatus according to any one of (50) to (52), in which the second electrical path includes:
an annular conductor disposed below the base,
a first connection conductor configured to electrically connect the annular conductor and the base via the first variable capacitor, and
a plurality of second connection conductors configured to electrically connect the annular conductor and the edge ring in parallel.
(64)

The plasma processing apparatus according to (63), in which the plurality of second connection conductors are connected in parallel to the annular conductor at equal intervals along a circumferential direction of the annular conductor.
(65)

The plasma processing apparatus according to (63) or (64), in which the plurality of second connection conductors are connected in parallel to the edge ring at equal intervals along a circumferential direction of the edge ring.
(66)

The plasma processing apparatus according to any one of (63) to (65), further including:
a connector configured to connect each of the second connection conductors and the annular conductor.
(67)

The plasma processing apparatus according to (66), in which the connector is configured to absorb a positional deviation between each of the second connection conductors and the annular conductor.
(68)

The plasma processing apparatus according to any one of (63) to (67),
in which the first connection conductor is connected to a first connection position of the annular conductor,
the annular conductor includes a plurality of conductor regions having different distances from the first connection position, and
the plurality of conductor regions are configured to have smaller electrical resistance as a distance from the first connection position increases.
(69)

The plasma processing apparatus according to any one of (50) to (62), in which the second electrical path includes:
an annular conductor disposed below the base,
a plurality of first connection conductors configured to electrically connect the annular conductor and the base in parallel, and
a plurality of second connection conductors configured to electrically connect the annular conductor and the edge ring in parallel, and
the first impedance adjustment mechanism is disposed in each of the plurality of first connection conductors.
(70)

The plasma processing apparatus according to (69), in which the plurality of first connection conductors are connected in parallel to the annular conductor at equal intervals along a circumferential direction of the annular conductor.
(71)

The plasma processing apparatus according to any one of (50) to (62),
in which the second electrical path includes a plurality of connection conductors configured to electrically connect the base and the edge ring in parallel, and
the first impedance adjustment mechanism is disposed in each of the plurality of connection conductors.
(72)

The plasma processing apparatus according to (71), in which the plurality of connection conductors are connected in parallel to the edge ring at equal intervals along a circumferential direction of the edge ring.
(73)

The plasma processing apparatus according to any one of (50) to (72), further including:
an RF power supply configured to supply an RF bias signal to the base.

Each of the above-described embodiments is described for the purpose of description, and it is not intended to limit the scope of the present disclosure. Each of the above-described embodiments may be modified in various ways without departing from the scope and gist of the present disclosure. For example, some configuration elements in one embodiment may be added to other embodiments. In addition, some configuration elements in one embodiment may be replaced with corresponding configuration elements in another embodiment.

According to one exemplary embodiment of the present disclosure, even when a pulsed DC signal is supplied, fluctuations in the base potential may be suppressed.

Reference to an element in the singular is not intended to mean “one and only one” unless explicitly so stated, but rather “one or more.” Moreover, where a phrase similar to “at least one of A, B, or C” is used in the claims, it is intended that the phrase be interpreted to mean that A alone may be present in an embodiment, B alone may be present in an embodiment, C alone may be present in an embodiment, or that any combination of the elements A, B and C may be present in a single embodiment; for example, A and B, A and C, B and C, or A and B and C.

No claim element herein is to be construed under the provisions of 35 U.S. C. 112(f) unless the element is expressly recited using the phrase “means for.” As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

The scope of the invention is indicated by the appended claims, rather than the foregoing description.

What is claimed is:

1. A plasma processing apparatus comprising:
a chamber;
a bias power supply configured to supply a pulsed bias DC signal;
a substrate support to support a substrate and an edge ring in the chamber; and
an electrical path,
wherein the substrate support includes
an electrostatic chuck including a first region to hold the substrate and a second region to hold the edge ring, the second region is located around the first region, and the electrostatic chuck includes a dielectric,
a first bias electrode is located inside the first region,
a second bias electrode is located inside the second region,
a base to support the electrostatic chuck, and
first impedance adjustment circuitry to have a first variable capacitor connected between the second bias electrode and the base, and
the electrical path includes
a first electrical path to connect the bias power supply, the base, and the first bias electrode, and
a second electrical path to connect the bias power supply, the base, the first impedance adjustment circuitry, and the second bias electrode.

2. The plasma processing apparatus according to claim 1, wherein the edge ring, the second region, and the second bias electrode are in an annular shape.

3. The plasma processing apparatus according to claim 1, wherein the first impedance adjustment circuitry has a switch that bypasses the first variable capacitor and connects the base and the second bias electrode.

4. The plasma processing apparatus according to claim 1, wherein the first impedance adjustment circuitry has a capacitor connected in parallel to a plasma load generated inside the chamber on a second bias electrode side of the first variable capacitor.

5. The plasma processing apparatus according to claim 1, further comprising:
a second impedance adjustment circuitry has a second variable capacitor connected between the first bias electrode and the base,
wherein the first electrical path connects the bias power supply, the base, the second impedance adjustment circuitry, and the first bias electrode.

6. The plasma processing apparatus according to claim 1, wherein the first region and the second region of the electrostatic chuck are integrated with each other.

7. The plasma processing apparatus according to claim 1, wherein the first region and the second region of the electrostatic chuck are separate bodies.

8. The plasma processing apparatus according to claim 7, wherein the base has a first upper structure to support the first region of the electrostatic chuck, a second upper structure to support the second region of the electrostatic chuck, and a lower structure to support the first upper structure and the second upper structure.

9. The plasma processing apparatus according to claim 8, wherein the first upper structure, the second upper structure, and the lower structure are integrated.

10. The plasma processing apparatus according to claim 9, wherein the base includes the first upper structure, the second upper structure, and the lower structure as separate bodies.

11. The plasma processing apparatus according to claim 1, further comprising:
an RF power supply configured to supply a source RF signal.

12. The plasma processing apparatus according to claim 11, wherein the source RF signal is supplied to at least one lower electrode or at least one upper electrode in the chamber to form a capacitively coupled plasma.

13. The plasma processing apparatus according to claim 11, wherein the source RF signal is supplied to an antenna disposed on or above the chamber to form an inductively coupled plasma.

14. The plasma processing apparatus according to claim 1, wherein the second electrical path includes:
an annular conductor located below the base,
a first connection conductor to electrically connect the annular conductor and the base via the first variable capacitor, and
a plurality of second connection conductors to electrically connect the annular conductor and the second bias electrode in parallel.

15. The plasma processing apparatus according to claim 14, wherein the plurality of second connection conductors are connected in parallel to the annular conductor at equal intervals along a circumferential direction of the annular conductor.

16. The plasma processing apparatus according to claim 14, wherein the plurality of second connection conductors are connected in parallel to the second bias electrode at equal intervals along a circumferential direction of the second bias electrode.

17. The plasma processing apparatus according to claim 14, further comprising:
a connector to connect each of the second connection conductors and the annular conductor.

18. The plasma processing apparatus according to claim 17, wherein the connector absorbs a positional deviation between each of the second connection conductors and the annular conductor.

19. The plasma processing apparatus according to claim 14,
wherein the first connection conductor is connected to a first connection position of the annular conductor,
the annular conductor includes a plurality of conductor regions having different distances from the first connection position, and
the plurality of conductor regions have a smaller electrical resistance as a distance from the first connection position increases.

20. The plasma processing apparatus according to claim 1, wherein the second electrical path includes:
an annular conductor located below the base,
a plurality of first connection conductors to electrically connect the annular conductor and the base in parallel, and
a plurality of second connection conductors to electrically connect the annular conductor and the second bias electrode in parallel, and
the first impedance adjustment circuitry is located in each of the plurality of first connection conductors.

21. The plasma processing apparatus according to claim 20, wherein the plurality of first connection conductors are connected in parallel to the annular conductor at equal intervals along a circumferential direction of the annular conductor.

22. The plasma processing apparatus according to claim 1,
wherein the second electrical path includes a plurality of connection conductors to electrically connect the base and the second bias electrode in parallel, and
the first impedance adjustment circuitry is located in each of the plurality of connection conductors.

23. The plasma processing apparatus according to claim 22, wherein the plurality of connection conductors are connected in parallel to the second bias electrode at equal intervals along a circumferential direction of the second bias electrode.

24. The plasma processing apparatus according to claim 1, further comprising:
an RF power supply configured to supply an RF bias signal to the base.

25. A substrate support to support a substrate and an edge ring in a chamber of a plasma processing apparatus, the substrate support comprising:
an electrostatic chuck including a first region to hold the substrate and a second region to hold the edge ring, the second region is located around the first region, and the electrostatic chuck includes a dielectric;
a first bias electrode is located inside the first region;
a second bias electrode is located inside the second region;
a base to support the electrostatic chuck;
impedance adjustment circuitry to have a variable capacitor connected between the second bias electrode and the base;
a first electrical path connecting the base, a bias power supply configured to supply a pulsed bias DC signal, and the first bias electrode; and
a second electrical path connecting the base, the bias power supply, the impedance adjustment circuitry, and the second bias electrode.

26. A plasma processing apparatus comprising:
a chamber;
a bias power supply configured to supply a pulsed bias DC signal;
a substrate support to support a substrate and an edge ring in the chamber; and
an electrical path,
wherein the substrate support includes
an electrostatic chuck including a first region to hold the substrate and a second region to hold the edge ring, the second region is located around the first region, and the electrostatic chuck includes a dielectric,
a first bias electrode is located inside the first region,
a second bias electrode is located inside the second region,
a base to support the electrostatic chuck, and
first impedance adjustment circuitry to have a first variable capacitor connected between the second bias electrode and the first bias electrode, and
the electrical path includes
a first electrical path to connect the bias power supply and the first bias electrode, and
a second electrical path to connect the bias power supply, the first bias electrode, the first impedance adjustment circuitry, and the second bias electrode.

27. A plasma processing apparatus comprising:
a chamber;
a bias power supply configured to supply a pulsed bias DC signal;
a substrate support to support a substrate and an edge ring in the chamber; and
an electrical path,
wherein the substrate support includes
an electrostatic chuck including a first region to hold the substrate and a second region to hold the edge ring, the second region is located around the first region, and the electrostatic chuck includes a dielectric,
a base to support the electrostatic chuck, and
first impedance adjustment circuitry to have a first variable capacitor connected between the base and the edge ring, and
the electrical path includes
a first electrical path to connect the bias power supply and the base, and
a second electrical path to connect the bias power supply, the base, the first impedance adjustment circuitry, and the edge ring.
